(19) United States
(12) Patent Application Publication
(10) Pub. No.: US 2026/0371839 A1
(43) Pub. Date: Nov. 19, 2026

(54) COMPOSITE MATERIAL, PREPARATION METHOD THEREFOR, AND LIGHT-EMITTING DEVICE

(71) Applicants: Guangdong Juhua Research Institute of Advanced Display, Guangzhou, Guangdong (CN); TCL Technology Group Corporation, Huizhou, Guangdong (CN)

(72) Inventor: Wenlin LIANG, Guangzhou, Guangdong (CN)

(73) Assignees: Guangdong Juhua Research Institute of Advanced Display, Guangzhou, Guangdong (CN); TCL Technology Group Corporation, Huizhou, Guangdong (CN)

(21) Appl. No.: 19/486,919

(22) PCT Filed: Sep. 27, 2023
(86) PCT No.: PCT/CN2023/122096

§ 371 Date: Nov. 21, 2025

(30) Foreign Application Priority Data
May 22, 2023 (CN) 202310582502.9

(51) Int. Cl. H10K 50/165; C07F 3/06; C07F 5/06; C07F 7/28; C07F 15/04; H10K 50/115; H10K 50/16; H10K 71/12; H10K 85/10; H10K 102/00

(52) U.S. Cl. CPC H10K 50/165; C07F 3/06; C07F 5/06; C07F 7/28; C07F 15/04; H10K 50/115; H10K 50/166; H10K 71/12; H10K 85/1135; H10K 85/141; H10K 2102/321

(57) ABSTRACT

A composite material, a preparation method therefor, and a light-emitting device are provided. The composite material includes an inorganic particle, and the inorganic particle is linked with a first ligand and a second ligand. In the composite material, bonding of the first ligand and the second ligand enables the adjacent inorganic particles to be linked, such that the composite material integrally forms a network structure. The composite material not only has relatively strong solution washing resistance, but also is matched with the work function of an electrode layer material, thus achieving a relatively high electron injection efficiency.

This present application claims priority of the Chinese patent application with the Chinese Patent Application No. 202310582502.9, filed in the China National Intellectual Property Administration on May 22, 2023, and entitled “COMPOSITE MATERIAL, PREPARATION METHOD THEREFOR, LIGHT-EMITTING DEVICE, AND DISPLAY DEVICE”, which is incorporated herein by reference in its entirety.

### TECHNICAL FIELD

The present disclosure relates to a field of display technology, and in particular to a composite material, a preparation method therefor, and a light-emitting device.

### BACKGROUND

In conventional electroluminescent devices, an inorganic material is generally used for the electron transport layer. For a light-emitting device with an inverted structure, the inorganic material itself is susceptible to be washed by solvents and has a work function that is mismatched with that of the material of the electrode layer, resulting in non-uniform film formation of the electron transport layer and poor electron injection efficiency, which affects the device performance.

### Technical Solutions

Embodiments of the present application provide a composite material, a preparation method therefor, a light-emitting device, and a display device. The composite material is used as an electron transport layer to be suitable for light-emitting devices with various structures, so as to improve the electron injection capability and electron transport capability of the device, and achieve the effects of improving the lifetime and stability of the device.

Embodiments of the present application provide a composite material, including an inorganic particle, the inorganic particle is linked with a first ligand and a second ligand, and the first ligand is linked to the second ligand.

Optionally, the first ligand and the second ligand are linked through a covalent bond; and/or
the composite material has a network structure; and/or
a molar ratio of the first ligand to the second ligand ranges from 5:1 to 12:1; and/or
the first ligand is selected from at least one of a chain hydrocarbon having 1-30 carbon atoms, a cyclic hydrocarbon having 3-30 ring atoms, an aromatic hydrocarbon having 6-40 ring atoms, a carboxylic acid having 1-30 carbon atoms, an amine having 1-30 carbon atoms, and a thiol having 1-30 carbon atoms, which are unsubstituted or substituted with an amino group, a halogen, a hydroxyl group, a carboxyl group, a nitro group, a sulfonic acid group, an aldehyde group, a mercapto group, or a cyano group; and/or
the second ligand is selected from at least one of a ketone, a ketone derivative, a quinone, and a quinone derivative.

Optionally, the first ligand is selected from at least one of R₁—CH₃, R₂—COOH, R₃—NH₂, and R₄—SH; where R₁, R₂, R₃, and R₄ are each independently selected from any one of a chain hydrocarbon group having 1-20 carbon atoms and an aromatic hydrocarbon group having 6-18 ring atoms, which are unsubstituted or substituted with an amino group, a halogen, a hydroxyl group, a carboxyl group, a nitro group, a sulfonic acid group, an aldehyde group, a mercapto group, or a cyano group; and/or
the second ligand is selected from one of R₅—CO—R₆, R₇—CO-M-CO—R₈, cyclohexadienedione and a derivative thereof; where R₅, R₆, R₇, and R₈ are each independently selected from any one of a hydrocarbon group having 1-20 carbon atoms and an aromatic hydrocarbon group having 6-18 ring atoms, which are unsubstituted or substituted with an amino group, a halogen, a hydroxyl group, a carboxyl group, a nitro group, a sulfonic acid group, an aldehyde group, a mercapto group, or a cyano group; and M is selected from one of a single bond, —O—, —S—, —CO—, —CO—O—, —O—CO—, —O—CO—O—, —CH═N—, —N═CH—, —N═N—, a hydrocarbylene group having 1-20 carbon atoms, and an arylene group having 5-18 ring atoms.

Optionally, the first ligand is selected from at least one of R₁—CH₃, R₂—COOH, R₃—NH₂, and R₄—SH; where R₁, R₂, R₃ and R₄ are each independently selected from one of a chain hydrocarbon group having 4-18 carbon atoms and an aromatic hydrocarbon group having 6-18 ring atoms; and/or

the second ligand is selected from at least one of the following formulas (1) to (6):

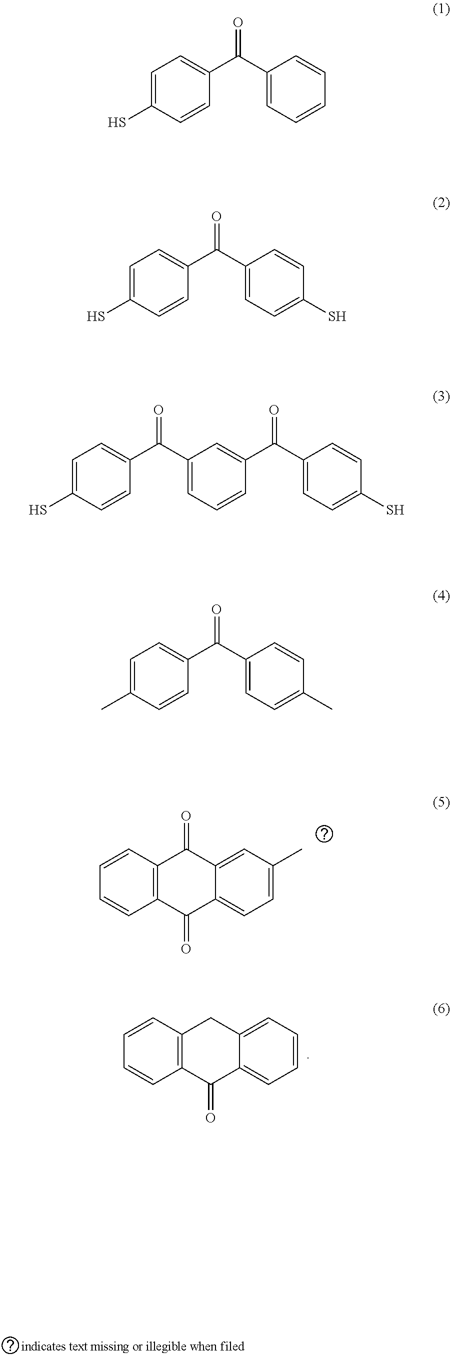

Optionally, the inorganic particle is selected from at least one of a metal oxide and a doped metal oxide; where a doping substance in the doped metal oxide is selected from at least one of a metal, a halogen, an inorganic substance, and an organic polymer; and/or
an average particle size of the inorganic particle ranges from 10 nm to 15 nm.

Optionally, the metal oxide is selected from at least one of ZnO, NiO, W₂O₃, Mo₂O₃, TiO₂, SnO, ZrO₂, Ta₂O₃, Ga₂O₃, Al₂O₃, CaO, and HfO₂; and/or
the metal is selected from at least one of Mg, Ca, Li, Ga, Al, Co, Mn, and K; and/or
the halogen is selected from one or more of F, Cl, Br, and I; and/or
the inorganic substance is selected from at least one of graphene, fullerene, and molybdenum disulfide; and/or
the organic polymer is selected from one or more of PEDOT:PSS, polyaniline, polypyrrole, polythiophene, and poly(p-phenylene vinylene).

Correspondingly, the embodiment of the present application further provides a method for preparing a composite material, including the following steps:
providing a first solution containing a metal source and a first ligand, and a second solution containing a second ligand;
mixing the first solution with an alkaline solution to obtain a third solution, and the third solution includes an inorganic particle linked with the first ligand; and
mixing the third solution with the second solution, followed by reacting, centrifuging, and precipitating to obtain the composite material; and the composite material includes the inorganic particle, the inorganic particle is linked with the first ligand and the second ligand, and the first ligand is linked to the second ligand.

Optionally, a metal in the metal source is a first metal, and the first metal is selected from one or more of Zn, Ni, W, Mo, Ti, Sn, Zr, Ta, Ga, Al, Ca, and Hf; and/or
the first solution further includes a doping source, and a doping substance in the doping source is selected from one or more of a second metal, a halogen, an inorganic substance, and an organic polymer.

Optionally, a molar ratio of the metal source, the doping source, the first ligand, and an alkali in the alkaline solution is (2-5):(0.1-0.2):1:1; and/or
a molar ratio of the inorganic particles linked to the first ligand to the second ligand is (5-12):1; and/or
a molar ratio of the first ligand to the second ligand is (5-12):1.

Optionally, the second metal is selected from at least one of Mg, Ca, Li, Ga, Al, Co, Mn, and K; and/or
the halogen is selected from at least one of F, Cl, Br, and I; and/or
the inorganic substance is selected from one or more of graphene, fullerene, and molybdenum disulfide; and the organic polymer is selected from one or more of PEDOT:PSS, polyaniline, polypyrrole, polythiophene, and poly(p-phenylene vinylene).

Furthermore, the present application further provides a light-emitting device, including a first electrode, a light-emitting layer, and a second electrode; and the light-emitting device further includes at least one electron transport layer disposed between the first electrode and the light-emitting layer;
where the electron transport layer includes a composite material, the composite material includes an inorganic particle, the inorganic particle is linked with a first ligand and a second ligand, and the first ligand is linked to the second ligand.

Optionally, the electron transport layer includes a first electron transport layer and a second electron transport layer that are stacked; the first electrode is an anode, and the second electrode is a cathode; or the first electrode is a cathode, and the second electrode is an anode;
the composite material of the first electron transport layer includes a first inorganic particle, the first inorganic particle is selected from a first doped metal oxide, and a doping substance in the first doped metal oxide is selected from at least one of Ga, Li, Mg, Mn, and a halogen;

the composite material of the second electron transport layer includes a second inorganic particle, the second inorganic particle is selected from a second doped metal oxide, and a doping substance in the second doped metal oxide is selected from at least one of Al, K, graphene, fullerene, molybdenum disulfide, PEDOT:PSS, polyaniline, polypyrrole, polythiophene, and poly(p-phenylene vinylene).

Optionally, a material of the anode and/or a material of the cathode include one or more of a metal, a carbon material, and a metal oxide; the metal includes one or more of Al, Ag, Cu, Mo, Au, Ba, Ca, Yb, and Mg; the carbon material includes one or more of graphite, a carbon nanotube, graphene, and a carbon fiber; the metal oxide includes one or more of a doped or undoped metal oxide, and the doped metal oxide includes one or more of ITO, FTO, ATO, AZO, GZO, IZO, MZO, and AMO; or the cathode is a composite electrode with a metal sandwiched between doped or undoped transparent metal oxides, and the composite electrode includes one or more of AZO/Ag/AZO, AZO/AI/AZO, ITO/Ag/ITO, ITO/AI/ITO, ZnO/Ag/ZnO, ZnO/Al/ZnO, ZnS/Ag/ZnS, ZnS/Al/ZnS, TiO₂/Ag/TiO₂, and TiO₂/Al/TiO₂.

Optionally, the light-emitting layer includes a quantum dot material, the light-emitting layer is a quantum dot light-emitting layer or an organic light-emitting layer; a material of the quantum dot light-emitting layer includes at least one of a single-structure quantum dot and a core-shell structure quantum dot; a material of the single-structure quantum dot is selected from at least one of a II-VI group compound, a IV-VI group compound, a III-V group compound, and a I-III-VI group compound. The II-VI group compound is selected from at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the IV-VI group compound is selected from at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the III-V group compound is selected from at least one of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb; and the I-III-VI group compound is selected from one or more of CuInS₂, CuInSe₂, and AgInS₂; and/or
a core of the core-shell structure quantum dot includes any one of the above-mentioned single-structure quantum dots, and a shell material of the core-shell structure quantum dot includes one or more of CdS, CdTe, CdSeTe, CdZnSe, CdZnS, CdSeS, ZnSe, ZnSeS, ZnS, and the above-mentioned material of the single-structure quantum dot; a material of the organic light-emitting layer includes at least one of 4,4′-bis(N-carbazolyl)-1,1′-biphenyl: tris[2-(p-tolyl)pyridine-C2,N)iridium (III), 4,4′,4″-tris(carbazol-9-yl)triphenylamine: tris[2-(p-tolyl)pyridine-C2,N)iridium (III), a diaryl anthracene derivative, a styryl aromatic derivative, a pyrene derivative, a fluorene derivative, a TBPe fluorescent material, a TTPX fluorescent material, a TBRb fluorescent material, a DBP fluorescent material, polyacetylene and a derivative thereof, poly(p-phenylene) and a derivative thereof, polythiophene and a derivative thereof, and polyfluorene and a derivative thereof.

Optionally, the light-emitting device further includes an electron injection layer, a hole transport layer, and a hole injection layer;
the electron injection layer is disposed between the first electrode and the electron transport layer, and a material of the electron injection layer includes an inorganic material and/or an organic material; the inorganic material is selected from one or more of doped or undoped zinc oxide, barium oxide, aluminum oxide, nickel oxide, titanium oxide, tin oxide, tantalum oxide, zirconium oxide, lithium-doped titanium oxide, aluminum-doped zinc oxide, manganese-doped zinc oxide, tin-doped zinc oxide, lithium-doped zinc oxide, indium tin oxide, cadmium sulfide, zinc sulfide, molybdenum sulfide, tungsten sulfide, copper sulfide, zinc stannide, indium phosphide, gallium phosphide, copper indium sulfide, copper gallium sulfide, and barium titanate, where a doping element includes one or more of aluminum, magnesium, lithium, manganese, yttrium, lanthanum, copper, nickel, zirconium, cerium, and gadolinium; the organic material is selected from one or more of a quinoxaline compound, an imidazole compound, a triazine compound, a fluorene-containing compound, and a hydroxyquinoline compound; and/or
the hole transport layer is disposed between the light-emitting layer and the second electrode, and the hole injection layer is disposed between the hole transport layer and the second electrode; and a material of the hole transport layer and/or a material the hole injection layer includes at least one of TFB, CuPc, PVK, Poly-TPD, DNTPD, TCATA, TCCA, CBP, TPD, NPB, NPD, PEDOT:PSS, TAPC, MCC, F4-TCNQ, HATCN, 4,4′,4′-tris(N-3-methylphenyl-N-phenylamino)triphenylamine, polyaniline, a transition metal oxide, a transition metal sulfide, a transition metal stannide, doped graphene, undoped graphene, and C60.

Furthermore, the present application provides a method for preparing a light-emitting device, including the following steps:
providing a substrate including a first electrode;
forming at least one electron transport layer on the first electrode;
forming a light-emitting layer on the electron transport layer; and
forming a second electrode on the light-emitting layer; or
providing a substrate including a second electrode;
forming a light-emitting layer on the second electrode;
forming at least one electron transport layer on the light-emitting layer; and
forming a first electrode on the electron transport layer;
where the electron transport layer includes the composite material or the composite material prepared by the method for preparing the composite material.

Optionally, steps of forming at least one electron transport layer includes:
depositing a solution containing the composite material on the first electrode, and followed by reacting to form the electron transport layer; or
depositing a solution containing the composite material on a side of the light-emitting layer away from the second electrode, and followed by reacting to form the electron transport layer.

Furthermore, the present application further provides a display device. The display device includes the light-emitting device, or the display device includes a light-emitting device obtained by the preparation method above.

### Beneficial Effects

Compared with the prior art, the composite material of the present application includes an inorganic particle linked with a first ligand and a second ligand. Because the first ligand and the second ligand are linked by bonding, the inorganic particles are interconnected to form a composite material with a network structure. Consequently, the composite material has relatively strong solution washing resistance, and may form a uniform film. A light-emitting device includes the composite material has a high electron injection efficiency.

### BRIEF DESCRIPTION OF DRAWINGS

To more clearly illustrate the technical solutions in the embodiments of the present application, the drawings to be used in the description of the embodiments are briefly introduced below. It is apparent that the drawings in the following description are merely some embodiments of the present application. For a person of ordinary skill in the art, other drawings may be obtained based on these drawings without creative effort.

FIG. 1 is a schematic flowchart of a method for preparing a composite material according to an embodiment of the present application;

FIG. 2 is a schematic flowchart of another method for preparing a composite material according to an embodiment of the present application;

FIG. 3 is a schematic structural diagram of an inorganic particle according to an embodiment of the present application;

FIG. 4 is a schematic diagram of the connection between inorganic particles according to an embodiment of the present application;

FIG. 5 is a schematic structural diagram of a light-emitting device according to an embodiment of the present application;

FIG. 6 is a schematic structural diagram of another light-emitting device according to an embodiment of the present application;

FIG. 7 is a schematic flowchart of a method for preparing a light-emitting device according to the present application;

FIG. 8 is a schematic flowchart of another method for preparing a light-emitting device according to the present application;

FIG. 9 is a schematic flowchart of a method for preparing a light-emitting device according to Example 9 of the present application;

FIG. 10 is a schematic flowchart of a method for preparing a light-emitting device according to Example 10 of the present application;

FIG. 11 is a schematic flowchart of a method for preparing a light-emitting device according to Example 11 of the present application;

FIG. 12 is a schematic flowchart of a method for preparing a light-emitting device according to Example 12 of the present application;

FIG. 13 is a schematic flowchart of a method for preparing a light-emitting device according to Comparative Example 1 of the present application;

FIG. 14 is a schematic flowchart of a method for preparing a light-emitting device according to Comparative Example 2 of the present application;

FIG. 15 is a schematic flowchart of a method for preparing a light-emitting device according to Comparative Example 3 of the present application;

FIG. 16 is a schematic diagram of the surface morphology of an electron transport layer in a light-emitting device according to Example 9 of the present application;

FIG. 17 is a schematic diagram of the surface morphology of an electron transport layer in a light-emitting device according to Example 10 of the present application;

FIG. 18 is a schematic diagram of the surface morphology of an electron transport layer in a light-emitting device according to Comparative Example 1 of the present application;

FIG. 19 is a schematic diagram of the surface morphology of an electron transport layer in a light-emitting device according to Comparative Example 2 of the present application.

Reference numerals: 110, first electrode; 120, electron transport layer; 130, light-emitting layer; 140, second electrode; 1211, first electron transport layer; 1212, second electron transport layer.

### DETAILED DESCRIPTION OF THE EMBODIMENTS

The technical solutions in the embodiments of the present application will be clearly and completely described below with reference to the accompanying drawings in the embodiments of the present application. Obviously, the described embodiments are merely a part of the embodiments of the present application, rather than all of the embodiments. Based on the embodiments in the present application, all other embodiments obtained by those skilled in the art without creative work shall fall within the protection scope of the present application. In addition, in the description of the present application, the term “comprising” means “comprising but not limited to”. The terms “first”, “second”, “third”, and the like are used for identification purposes only and do not impose numerical requirements or establish an order. The various embodiments of the present application may be described in the form of a range. It should be understood that such a description is merely for convenience and brevity and should not be construed as a rigid limitation on the scope of the present application. Therefore, the description of a range should be considered to have specifically disclosed all possible sub-ranges and individual numerical values within that range. For example, a range described as from 1 to 6 should be considered to have specifically disclosed sub-ranges such as from 1 to 3, from 1 to 4, from 1 to 5, from 2 to 4, from 2 to 6, from 3 to 6, etc., as well as individual numbers within that range, such as 1, 2, 3, 4, 5, and 6. This applies regardless of the breadth of the range. In addition, whenever a numerical range is indicated herein, it is intended to include any referenced numbers (fractions or integers) within the indicated range.

During research and practice, the inventors of the present application found that the structure of a conventional electroluminescent device is generally anode/hole injection layer/hole transport layer/light-emitting layer/electron transport layer/cathode. In this structure, the electron transport layer is generally formed of ZnO, TiO₂, LiF, or the like, and the cathode is generally formed of a low work function metal material such as Mg, Ag, Al, or the like. Since the cathode materials are sensitive to water and oxygen, and are prone to chemical reactions, the lifetime of conventional electroluminescent devices is reduced, and stability is poor, which is not conducive to commercial applications. To improve the stability of the device, using an inverted device structure is an effective method. However, in an inverted electroluminescent device structure, the material of the electron transport layer is susceptible to be washed by the organic solvent used to prepare the next functional layer, which degrades or even nullifies the function of the electron transport layer, increases its roughness, and adversely affects film formation. Moreover, an inverted electroluminescent device structure usually uses an anode of the conventional electroluminescent device as the cathode. Since the work function of the anode material is usually high, a large electron injection barrier exists when it is used as a cathode, causing a work function mismatch problem. This leads to poor electron injection efficiency and an electron-hole imbalance, and resulting in poor device performance.

Therefore, how to overcome the problems of uneven film formation, easy washing, inability to prevent the chemical reaction of water and oxygen, and electron injection efficiency of the electron transport layer is one of the keys to improve the performance of electroluminescent devices.

Embodiments of the present application provide a composite material and a preparation method therefor, a light-emitting device and a preparation method therefor, and a display device. Hereinafter, each of them will be described in detail below, respectively. It should be noted that the order of description of the following embodiments does not constitute a limitation on the preferred order of the embodiments.

An embodiment of the present application provides a composite material. The composite material includes an inorganic particle. The inorganic particle is linked with a first ligand and a second ligand, and the first ligand is linked to the second ligand.

It can be understood that the composite material includes a plurality of inorganic particles. When the first ligand is linked to the second ligand, the plurality of inorganic particles may be linked to each other to form a network structure.

Furthermore, the inorganic particle of the present application is dual-ligand inorganic particle to which both the first ligand and the second ligand are linked. The presence of multiple ligands imparts high solvent selectivity to the composite material. The first ligand and the second ligand have mutually reactive groups, enabling bonding between the first ligand and the second ligand. The principle of bonding is as follows: under the influence of external factors, free radicals are generated on the first ligand and the second ligand, and the free radicals react with each other to form a covalent bond, thereby linking adjacent inorganic particles. It can be understood that the aforementioned linking process has a degree of randomness. However, due to steric hindrance, the first ligand linked to one inorganic particle will tend to preferentially bond with the second ligand linked to another inorganic particle, and the second ligand linked to one inorganic particle will tend to preferentially bond with the first ligand linked to another inorganic particle. Moreover, the link between multiple inorganic particles is not limited to bonding through only a single pair of the first ligand and the second ligand. The links between different inorganic particles allow the composite material as a whole to form a network structure.

Because the composite material of the present application has a network structure, it may not only partially block water and oxygen from contacting the electrode material, reducing the probability of chemical reactions in the electrode material, but also resist washing by organic solvents. The composite material has strong resistance to solution washing and high stability, thereby may solve the problems of low lifetime and poor stability of conventional light-emitting device, and may further solve the problems of difficult electron injection caused by high work function of the electrode layer in inverted device.

In some embodiments, the method of bonding between the first ligand and the second ligand may include, for example, photoinitiated polymerization, thermally initiated polymerization, or the like. The preferred method is photoinitiated polymerization because the method of photoinitiated polymerization is simple, and the ligands used for photoinitiated polymerization are structurally engineered molecular scaffolds, which facilitates the formation of an integrally cross-linked and overall network structure.

In some embodiments, a molar ratio of the first ligand to the second ligand ranges from 5:1 to 12:1. It can be understood that the molar ratio of the first ligand to the second ligand may be any one of 5:1, 6:1, 7:1, 8:1, 9:1, 10:1, 11:1, and 12:1, or a range between any two thereof.

In some embodiments, the first ligand is selected from one or more of a chain hydrocarbon having 1-30 carbon atoms, a cyclic hydrocarbon having 3-30 ring atoms, an aromatic hydrocarbon having 6-40 ring atoms, a carboxylic acid having 1-30 carbon atoms, an amine having 1-30 carbon atoms, and a thiol having 1-30 carbon atoms, and which are unsubstituted or substituted with an amino group, a halogen, a hydroxyl group, a carboxyl group, a nitro group, a sulfonic acid group, an aldehyde group, a mercapto group, or a cyano group. The second ligand is selected from one or more of a ketone, a ketone derivative, a quinone, and a quinone derivative. It can be understood that the first ligand is a dispersing ligand. The dispersing ligand has high selectivity and high degrees of freedom, which imparts versatility and freedom in solvent selection. The second ligand is a photocrosslinking ligand, and preferably a photoinitiator. Under the action of ultraviolet light, the free radicals of the photocrosslinking ligand are activated, and the free radicals may form covalent bonds with the dispersing ligand of adjacent inorganic particle. The photocrosslinking ligand is a structurally engineered molecular scaffold, thereby achieving integral cross-linking and overall network structure.

Furthermore, the first ligand is selected from at least one of R₁—CH₃, R₂—COOH, R₃—NH₂, and R₄—SH. R₁, R₂, R₃, and R₄ are each independently selected from any one of a chain hydrocarbon group having 1-20 carbon atoms and an aromatic hydrocarbon group having 6-18 ring atoms, and the chain hydrocarbon group and the aromatic hydrocarbon group are unsubstituted or substituted with an amino group, a halogen, a hydroxyl group, a carboxyl group, a nitro group, a sulfonic acid group, an aldehyde group, a mercapto group, or a cyano group. The second ligand is selected from one of R₅—CO—R₆, R₇—CO-M-CO—R₈, cyclohexadienedione or a derivative thereof. R₅, R₆, R₇, and R₈ are each independently selected from any one of a hydrocarbon group having 1-20 carbon atoms and an aromatic hydrocarbon group having 6-18 ring atoms, and the hydrocarbon group and the aromatic hydrocarbon group are unsubstituted or substituted with an amino group, a halogen, a hydroxyl group, a carboxyl group, a nitro group, a sulfonic acid group, an aldehyde group, a mercapto group, or a cyano group. M is selected from one of a single bond, —O—, —S—, —CO—, —CO—O—, —O—CO—, —O—CO—O—, —CH═N—, —N═CH—, —N—N—, a hydrocarbylene group having 1-20 carbon atoms, and an arylene group having 5-18 ring atoms. It can be understood that the hydrocarbylene group refers to a divalent hydrocarbon group obtained by removing two hydrogen atoms from a hydrocarbon, and the arylene group refers to a divalent aromatic group obtained by removing two hydrogen atoms from an aromatic ring.

Furthermore, the first ligand is selected from at least one of R₁—CH₃, R₂—COOH, R₃—NH₂, and R₄—SH. R₁, R₂, R₃ and R₄ are each independently selected from any one of a chain hydrocarbon group having 4-18 carbon atoms and an aromatic hydrocarbon group having 6-18 ring atoms. Herein, the chain hydrocarbon group refers to a group containing only carbon atom and hydrogen atom, generally a radical remaining after the corresponding hydrocarbon loses one hydrogen atom. There are many types of chain hydrocarbon groups. A monovalent saturated group is also called an alkyl group, and a monovalent unsaturated group is also called an alkenyl group or an alkynyl group. The aromatic hydrocarbon group refers to an organic group having aromatic ring, which must contain at least one conjugated double bond and at least one carbon atom, and the carbon atom may be bonded to other atoms, such as hydrogen, oxygen, nitrogen, and the like.

Furthermore, the second ligand is selected from one or more of the following formulas (1) to (6):

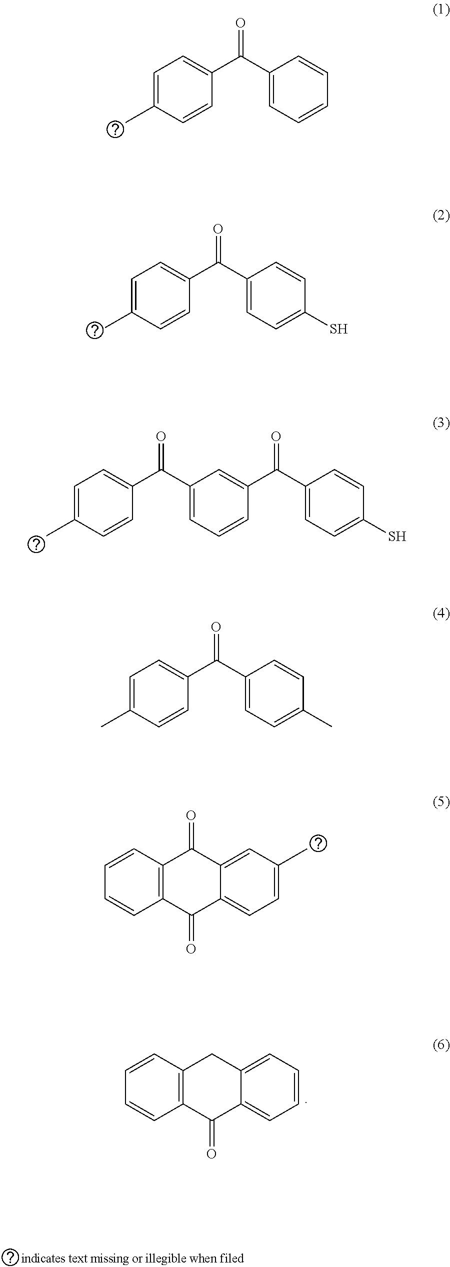

Where, the molecular formula of the compound of formula (1) is C₁₃H₁₀OS, and the CAS number is 1620-94-6; the molecular formula of the compound of formula (2) is C₁₃H₁₀OS₂, and the CAS number is 37089-83-1; the molecular formula of formula (3) is C₂₀H₁₄O₂S₂, and the CAS number is 180286-04-8; the molecular formula of formula (4) is C₁₅H₁₄O, and the CAS number is 611-97-2; the molecular formula of formula (5) is C₁₄H₇IO₂, and the CAS number is 10566-32-2; the molecular formula of formula (6) is C₁₄H₁₀O, and the CAS number is 90-44-8.

In some embodiments, the inorganic particle is selected from one or more of a metal oxide and a doped metal oxide. A doping substance in the doped metal oxide is selected from at least of a metal, a halogen, an inorganic substance, and an organic polymer. It can be understood that when the doping substance is the metal, the metal used for doping is a different metal from the metal in the metal oxide. The organic polymer is a highly conductive polymer. It can be understood that when the inorganic particle is selected from the metal oxide or the doped metal oxide, the composite material may be used as an electron transport material.

In some embodiments, the metal oxide is selected from at least one of ZnO, NiO, W₂O₃, Mo₂O₃, TiO₂, SnO, ZrO₂, Ta₂O₃, Ga₂O₃, Al₂O₃, CaO, and HfO₂.

In some embodiments, the metal is selected from at least one of Mg, Ca, Li, Ga, Al, Co, Mn, and K.

In some embodiments, the halogen is selected from at least one or F, Cl, Br, and I.

In some embodiments, the inorganic substance is selected from at least one of graphene, fullerene, and molybdenum disulfide.

In some embodiments, the organic polymer is selected from one or more of poly(3,4-ethylenedioxythiophene) polystyrene sulfonate (PEDOT:PSS), polyaniline, polypyrrole, polythiophene, and poly(p-phenylene vinylene).

Furthermore, the function of the composite materials varies depending on the doping substance used. For example, doping with metal elements such as Ga, Li, Mg, and Mn, or with halogen atoms may adjust the work function of the composite material; whereas doping with metal elements such as Al and K, or with inorganic compound or organic polymer may improve the electron transport performance of the composite material.

In some embodiments, an average particle size of the inorganic particle ranges from 10 nm to 15 nm; for example, the average particle size of the inorganic particle is any value of 10 nm, 11 nm, 12 nm, 13 nm, 14 nm, or 15 nm, or a range between any two thereof.

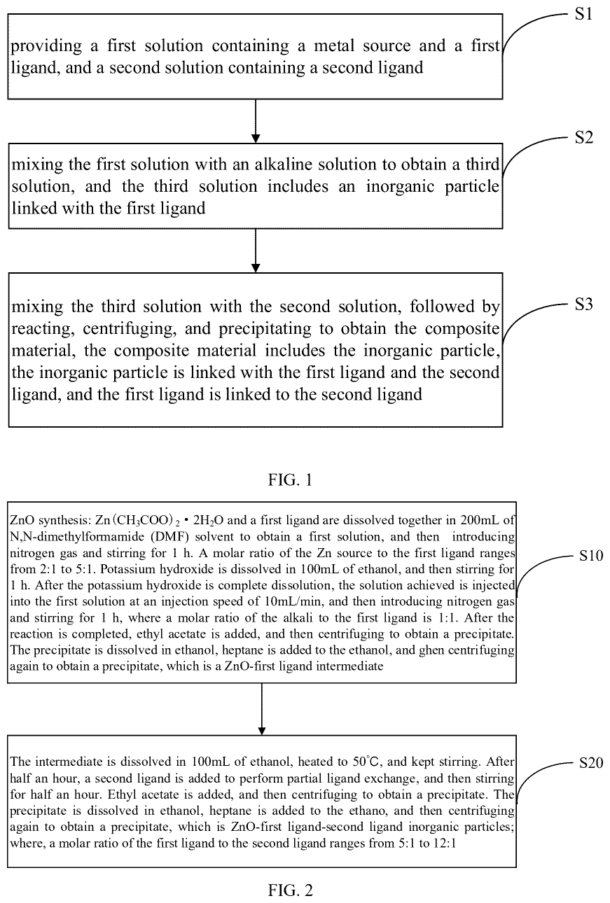

Referring to FIG. 1, an embodiment of the present application further provides a method for preparing a composite material, including the following steps:
providing a first solution containing a metal source and a first ligand, and a second solution containing a second ligand;
mixing the first solution with an alkaline solution to obtain a third solution, and the third solution includes an inorganic particle linked with the first ligand;
mixing the third solution with the second solution, followed by reacting, centrifuging, and precipitating to obtain the composite material, the composite material includes the inorganic particle, the inorganic particle is linked with the first ligand and the second ligand, and the first ligand is linked to the second ligand.

After the composite material of the present application is prepared by the method described above, consistency of particle size may be ensured. The composite material may be directly used in photolithography process or inkjet printing process that are commercially viable due to the structural control of the two kind of ligands. Furthermore, the original optical properties of the inorganic particle or the optoelectronic performance of subsequent device are not affected, and the material is suitable for any solution-based processing, such as inkjet printing or spin coating.

In some embodiments, a first metal in the metal source is selected from at least one of Zn, Ni, W, Mo, Ti, Sn, Zr, Ta, Ga, Al, Ca, and Hf.

In some embodiments, the first solution further includes a doping source. A doping substance in the doping source is selected from at least one of a second metal, a halogen, an inorganic substance, and an organic polymer.

Specifically, referring to FIG. 2, the composite material is prepared using a Zn source as the metal source and a potassium hydroxide solution as the alkaline solution. The specific synthesis process includes the following steps:

S11: ZnO synthesis: Zn(CH₃COO)₂·2H₂O and a first ligand are dissolved together in 200 mL of N,N-dimethylformamide (DMF) solvent to obtain a first solution, and then introducing nitrogen gas and stirring for 1 h. A molar ratio of the Zn source to the first ligand ranges from 2:1 to 5:1. Potassium hydroxide is dissolved in 100 mL of ethanol, and then stirring for 1 h. After the potassium hydroxide is complete dissolution, the solution achieved is injected into the first solution at an injection speed of 10 mL/min, and then introducing nitrogen gas and stirring for 1 h, where a molar ratio of the alkali to the first ligand is 1:1. After the reaction is completed, ethyl acetate is added, and then centrifuging to obtain a precipitate. The precipitate is dissolved in ethanol, heptane is added to the ethanol, and ghen centrifuging again to obtain a precipitate, which is a ZnO-first ligand intermediate.

S21: The intermediate is dissolved in 100 mL of ethanol, heated to 50 °C, and kept stirring. After half an hour, a second ligand is added to perform partial ligand exchange, and then stirring for half an hour. Ethyl acetate is added, and then centrifuging to obtain a precipitate. The precipitate is dissolved in ethanol, heptane is added to the ethano, and then centrifuging again to obtain a precipitate, which is ZnO-first ligand-second ligand inorganic particles; where, a molar ratio of the first ligand to the second ligand ranges from 5:1 to 12:1.

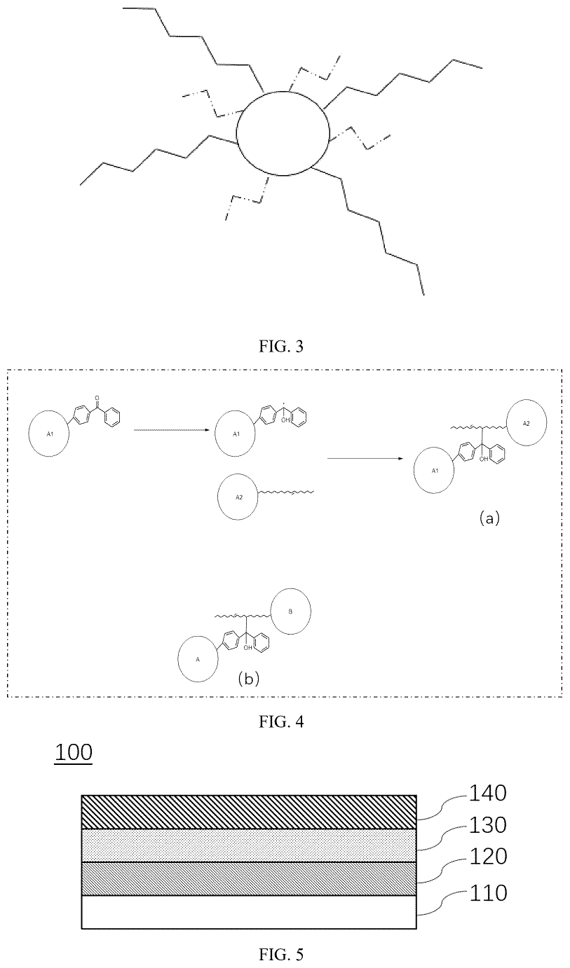

Referring to FIG. 3, which is a schematic structural diagram of the synthesized ZnO-first ligand-second ligand composite material. Based on the central inorganic particle ZnO, a plurality of first ligands and second ligands are linked to the surface of the inorganic particle, where the long solid lines represent the first ligand, and the short dashed lines represent the second ligand. FIG. 3 further shows a schematic diagram of the principle of reaction between inorganic particles. Under ultraviolet light irradiation, free radicals are generated on the second ligand, and the free radicals react and bond with the first ligand, thereby linking the inorganic particles. In FIG. 3, the link of inorganic particles may be a link between inorganic particles of the same type, as shown in (a) of FIG. 3, where A1 and A2 represent inorganic particles of the same type; or as shown in (b) of FIG. 3, where A and B respectively represent different types of inorganic particles, and different types of inorganic particles are linked through the bonding of the first ligand and the second ligand.

It can be understood that, in step S11, a doping source may also be added to improve the function of the inorganic particle. A molar ratio of the metal source, the doping source, the first ligand, and the alkali is (2-5):(0.1-0.2):1:1.

Meanwhile, a molar ratio of the inorganic particle linked with the first ligand to the second ligand is (5-12):1.

An embodiment of the present application provides a light-emitting device including a first electrode, a light-emitting layer, and a second electrode, wherein at least one electron transport layer is further disposed between the first electrode and the light-emitting layer. The electron transport layer includes a composite material. the composite material includes an inorganic particle, the inorganic particle is linked with a first ligand and a second ligand, and the first ligand is configured to linked with the second ligand.

Furthermore, a first electron transport layer and a second electron transport layer are stacked between the first electrode and the light-emitting layer. The first electrode is an anode, and the second electrode is a cathode; or, the first electrode is a cathode, and the second electrode is an anode.

The composite material of the first electron transport layer includes a first inorganic particle, the first inorganic particle is selected from a first doped metal oxide, and a doping substance in the first doped metal oxide is selected from at least one of Ga, Li, Mg, Mn, and a halogen.

The composite material of the second electron transport layer includes a second inorganic particle, the second inorganic particle is selected from a second doped metal oxide, and a doping substance in the second doped metal oxide is selected from at least one of Al, K, graphene, fullerene, molybdenum disulfide, poly(3,4-ethylenedioxythiophene) polystyrene sulfonate (PEDOT:PSS), polyaniline, polypyrrole, polythiophene, and poly(p-phenylene vinylene).

It can be understood that the first electron transport layer may be used to adjust the work function of the electron transport layer, and the second electron transport layer may be used to adjust the transport capability of the electron transport layer.

Furthermore, the light-emitting layer is a quantum dot light-emitting layer or an organic light-emitting layer. A material of the quantum dot light-emitting layer includes at least one of a single-structure quantum dot and a core-shell structure quantum dot. A material of the single-structure quantum dot is selected from at least one of a II-VI group compound, a IV-VI group compound, a III-V group compound, and a I-III-VI group compound. The II-VI group compound is selected from at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the IV-VI group compound is selected from at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the III-V group compound is selected from at least one of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb; and the I-III-VI group compound is selected from at least one of CuInS₂, CuInSe₂, and AgInS₂.

A core of the core-shell structure quantum dot includes any one of the above-mentioned single-structure quantum dots, and a shell material of the core-shell structure quantum dot includes at least one of CdS, CdTe, CdSeTe, CdZnSe, CdZnS, CdSeS, ZnSe, ZnSeS, ZnS, and the above-mentioned material of the single-structure quantum dot. A material of the organic light-emitting layer includes at least one of 4,4′-bis(N-carbazolyl)-1,1′-biphenyl: tris[2-(p-tolyl)pyridine-C₂,N)iridium (III), 4,4′,4″-tris(carbazol-9-yl)triphenylamine: tris[2-(p-tolyl)pyridine-C₂,N)iridium (III), a diaryl anthracene derivative, a styryl aromatic derivative, a pyrene derivative, a fluorene derivative, a TBPe fluorescent material, a TTPX fluorescent material, a TBRb fluorescent material, a DBP fluorescent material, polyacetylene and a derivative thereof, poly(p-phenylene) and a derivative thereof, polythiophene and a derivative thereof, and polyfluorene and a derivative thereof.

In some embodiments, a material of the cathode may be one or more of a metal, a carbon-silicon material, and a metal oxide. The metal may be, for example, one or more of Al, Ag, Cu, Mo, Au, Ba, Ca, and Mg; the carbon-silicon material may be, for example, one or more of silicon, graphite, a carbon nanotube, graphene, and a carbon fiber; the metal oxide may be a doped or undoped metal oxide, and the doped metal oxide includes one or more of indium tin oxide (ITO), fluorine-doped tin oxide (FTO), antimony-doped tin oxide (ATO), aluminum-doped zinc oxide (AZO), gallium-doped zinc oxide (GZO), indium zinc oxide (IZO), magnesium zinc oxide (MZO), and aluminum molybdenum oxide (AMO). The cathode may also be a composite electrode with a metal sandwiched between doped or undoped transparent metal oxides, and the composite electrode includes but not limited to one or more of AZO/Ag/AZO, AZO/AI/AZO, ITO/Ag/ITO, and ITO/Al/ITO. Preferably, a thickness of the cathode layer ranges from 10 nm to 1000 nm.

In some embodiments, a material of the anode may be one or more of a metal, a carbon-silicon material, and a metal oxide. The metal may be, for example, one or more of Al, Ag, Cu, Mo, Au, Ba, Ca, Yb, and Mg; the carbon-silicon material may be, for example, one or more of silicon, graphite, a carbon nanotube, graphene, and a carbon fiber; the metal oxide may be a doped or undoped metal oxide, and the doped metal oxide includes one or more of indium tin oxide (ITO), fluorine-doped tin oxide (FTO), antimony-doped tin oxide (ATO), aluminum-doped zinc oxide (AZO), gallium-doped zinc oxide (GZO), indium zinc oxide (IZO), magnesium zinc oxide (MZO), and aluminum molybdenum oxide (AMO). The anode may also be a composite electrode with a metal sandwiched between doped or undoped transparent metal oxides, and the composite electrode includes but not limited to one or more of AZO/Ag/AZO, AZO/AI/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂. Preferably, a thickness of the anode layer ranges from 10 nm to 1000 nm.

In some embodiments, the light-emitting device may have an inverted structure or a conventional structure.

In some embodiments, a hole transport layer and a hole injection layer are further stacked between the light-emitting layer and the second electrode layer. The hole transport layer is connected to the light-emitting layer. The hole injection layer is disposed between the hole transport layer and the second electrode, and is connected to the hole transport layer and the second electrode, respectively.

Furthermore, a material of the hole transport layer is selected from an organic material having hole transport capability, and the organic material may include but not limited to one or more of poly(9,9-dioctylfluorene-co-N-(4-butylphenyl)diphenylamine) (TFB), poly(N-vinylcarbazole) (PVK), poly[N,N′-bis(4-butylphenyl)-N,N′-bis(phenyl)benzidine] (poly-TPD), poly(9,9-dioctylfluorene-co-bis-N,N-phenyl-1,4-phenylenediamine) (PFB), 4,4′,4″-tris(carbazol-9-yl)triphenylamine (TCATA), 4,4′-bis(N-carbazolyl)-1,1′-biphenyl (CBP), N,N′-bis(3-methylphenyl)-N,N′-diphenylbenzidine (TPD), N,N′-di(naphthalen-1-yl)-N,N′-diphenyl-(1,1′-biphenyl)-4,4′-diamine (NPB), poly(3,4-ethylenedioxythiophene) polystyrene sulfonate (PEDOT:PSS), Spiro-NPB, Spiro-TPD, doped graphene, undoped graphene, and C60. A material of the hole transport layer may further be selected from an inorganic material having hole transport capability, and the inorganic material may include but not limited to one or more of doped or undoped NiO, MoO₃, WO₃, V₂O₅, P-type nitride, CrO₃, and CuO. A thickness of the hole transport layer may range from 20 nm to 100 nm.

Furthermore, a material of the hole injection layer is selected from a hole injection material. The hole injection material may be one or more of TFB, CuPc, PVK, Poly-TPD, DNTPD, TCATA, TCCA, CBP, TPD, NPB, NPD, PEDOT:PSS, TAPC, MCC, F4-TCNQ, HATCN, 4,4′,4″-tris(N-3-methylphenyl-N-phenylamino)triphenylamine, polyaniline, a transition metal oxide, a transition metal sulfide, a transition metal stannide, doped graphene, undoped graphene, C60, TiOPc (titanium phthalocyanine oxide), m-MTDATA (CAS 124729-98-2), 2-TNATA (4,4′,4″-tris(2-naphthylphenylamino)triphenylamine), a transition metal oxide, and a transition metal chalcogenide. The transition metal oxide includes one or more of NiOₓ, MoOₓ, WOₓ, CrOₓ, and CuO; the metal chalcogenide includes one or more of MoSₓ, MoSeₓ, WSₓ, WSeₓ, and CuS. The value of x in each compound may be determined according to the valence of the atoms in the compound. A thickness of the hole injection layer may range from 20 nm to 50 nm.

In some embodiments, an electron injection layer is further disposed between the first electrode and the electron transport layer, and a material of the electron injection layer includes an inorganic material and/or an organic material. The inorganic material is selected from one or more of doped or undoped zinc oxide, barium oxide, aluminum oxide, nickel oxide, titanium oxide, tin oxide, tantalum oxide, zirconium oxide, nickel oxide, lithium-doped titanium oxide, aluminum-doped zinc oxide, manganese-doped zinc oxide, tin-doped zinc oxide, lithium-doped zinc oxide, indium tin oxide, cadmium sulfide, zinc sulfide, molybdenum sulfide, tungsten sulfide, copper sulfide, zinc stannide, indium phosphide, gallium phosphide, copper indium sulfide, copper gallium sulfide, and barium titanate. A doping element includes one or more of aluminum, magnesium, lithium, manganese, yttrium, lanthanum, copper, nickel, zirconium, cerium, and gadolinium. The organic material is selected from one or more of a quinoxaline compound, an imidazole compound, a triazine compound, a fluorene-containing compound, and a hydroxyquinoline compound.

Referring to FIG. 5, a light-emitting device 100 includes a first electrode 110, a light-emitting layer 130, and a second electrode 140. An electron transport layer 120 is disposed between the first electrode 110 and the light-emitting layer 130. A material of the electron transport layer 120 is the composite material provided in this embodiment. Since the composite material includes an inorganic particle having a first ligand and a second ligand, and bonding occurs between the first ligand and the second ligand, so that the adjacent inorganic particles are linked and the composite material forms form a network structure as a whole. When the light-emitting device 100 has a conventional structure, the composite material with the network structure may prevent some water and oxygen from contacting the first electrode 110, thereby reducing the probability of a chemical reaction between the first electrode 110 and water or oxygen. When the light-emitting device 100 has an inverted structure, the network structure improves the overall strength of the composite material, which may prevent the composite material itself from being washed away by organic solvents, and making the composite material have highly resistant to solution washing and highly stable.

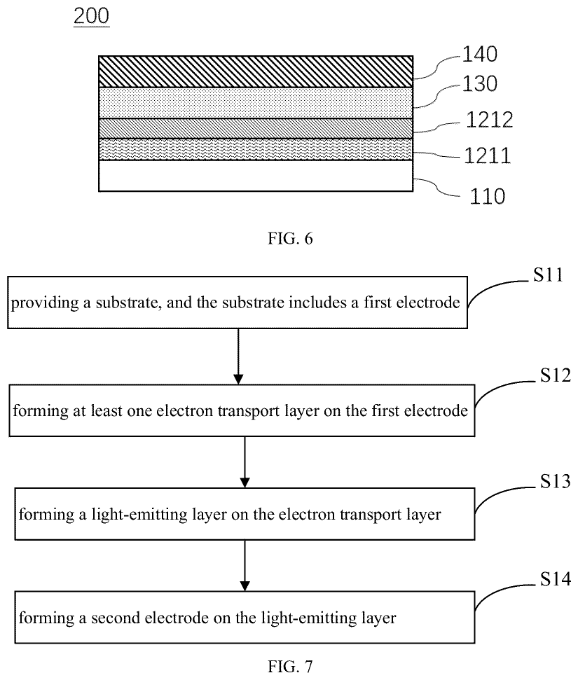

Referring to FIG. 6, a light-emitting device 200 includes a first electrode 110, a light-emitting layer 130, and a second electrode 140. A first electron transport layer 1211 and a second electron transport layer 1212 are stacked between the first electrode 110 and the light-emitting layer 130. The first electron transport layer 1211 is connected to the first electrode 110, and the second electron transport layer 1212 is connected to the light-emitting layer 130. The composite material of the first electron transport layer 1211 includes a first inorganic particle. The first inorganic particle is selected from a metal oxide doped with a first substance, and the first substance is selected from at least one of Ga, Li, Mg, Mn, and a halogen atom. Doping with the first substance enables the first electron transport layer 1211 to adjust the work function when in contact with the first electrode 110. By adjusting the work function, more electrons may escape from the first electrode 110. The composite material of the second electron transport layer 1212 includes a second inorganic particle, the second inorganic particle is selected from a metal oxide doped with a second substance, and the second substance is selected from at least one of Al, K, graphene, fullerene, molybdenum disulfide, poly(3,4-ethylenedioxythiophene) polystyrene sulfonate (PEDOT:PSS), polyaniline, polypyrrole, polythiophene, and polystyrene. Doping with the second substance may improve the electron transport capability of the second electron transport layer 1212, so that more electrons enter the light-emitting layer 130 when the second electron transport layer 1212 is in contact with the light-emitting layer 130, which reduces the electron injection barrier, improves the electron injection efficiency, and reduces the problem of electron-hole imbalance.

Referring to FIG. 7, an embodiment of the present application further provides a method for preparing a light-emitting device, including the following steps:
providing a substrate, and the substrate includes a first electrode;
forming at least one electron transport layer on the first electrode;
forming a light-emitting layer on the electron transport layer; and
forming a second electrode on the light-emitting layer;
where the electron transport layer includes the composite material as described in the present application or the composite material prepared by the preparation method of the composite material.

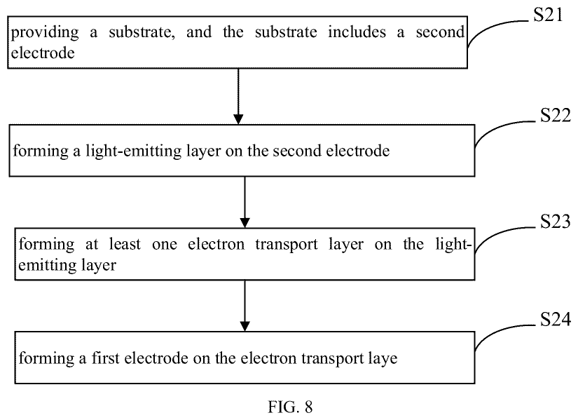

Alternatively, referring to FIG. 8, an embodiment of the present application further provides another method for preparing a light-emitting device, including the following steps:
providing a substrate, and the substrate includes a second electrode;
forming a light-emitting layer on the second electrode;
forming at least one electron transport layer on the light-emitting layer; and
forming a first electrode on the electron transport layer;
where the electron transport layer includes the composite material as described in the present application or the composite material prepared by the preparation method of the composite material.

Furthermore, the steps of forming at least one electron transport layer includes:
depositing a solution containing the composite material on the first electrode, and followed by reacting to form the electron transport layer; or
depositing a solution containing the composite material on a side of the light-emitting layer away from the second electrode, and followed by reacting to form the electron transport layer.

In some embodiments, the method for depositing the solution containing the composite material includes spin coating, drop casting, or printing.

In some embodiments, in the steps of forming the at least one electron transport layer, the formation process preferably includes first irradiating with ultraviolet (UV) light and then annealing. A wavelength of the UV light ranges from 300 nm to 400 nm, an energy density of the UV light ranges from 3 mW/cm² to 6 mW/cm², and an irradiation exposure time ranges from 10 s to 15 s. An annealing temperature ranges from 80 °C to 120 °C, and an annealing time ranges from 10 min to 15 min.

In some embodiments, the present application further provides a display device including the light-emitting device provided in the embodiments of the present application. Since the light-emitting device included in the display device has excellent luminous efficiency and overall performance, the display device further exhibits excellent luminous efficiency and overall performance.

To enable those skilled in the art to clearly understand the implementation details and operations of the present application, and to demonstrate the significant performance improvements of the composite material and the preparation method therefor, the light-emitting device and the preparation method therefor, and the display device of the embodiments of the present application, the following examples are provided to illustrate the above technical solutions.

### Example 1

This Example provides a composite material including an inorganic particle, the inorganic particles are linked with a first ligand and a second ligand, and the first ligand is configured to bond with the second ligand to link adjacent inorganic particles. The first ligand and the second ligand are linked through a covalent bond. The bonding method of the first ligand and the second ligand is photoinitiated polymerization. The composite material forms a network structure through the link of the inorganic particles.

The inorganic particle is ZnO doped with Mg, and denoted as ZnMgO. The first ligand is oleylamine with a molecular formula of CH₃ (CH₂)₇CH═CH(CH₂)₇CH₂NH₂, and denoted as OAm. The second ligand is:

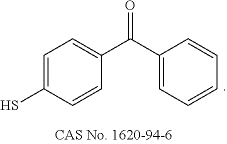 [SMILES: O=C(c1ccccc1)c1ccc(S)cc1]

A method for preparing the composite material of this Example includes the following steps:
0.12 mol of Zn(Ac)₂·2H₂O, 0.006 mol of Mg(Ac)₂·4H₂O, and 0.05 mol of oleylamine (OAm) were simultaneously dissolved in 200 mL of N,N-dimethylformamide (DMF) solvent to obtain a first solution, and then introduced nitrogen gas and stirred for 1 h; 0.05 mol of potassium hydroxide was dissolved in 100 mL of an ethanol solution, and then stirred for 1 h; after the potassium hydroxide was complete dissolution, the potassium hydroxide solution achieved was injected into the first solution at an injection rate of 10 mL/min, and then introduced nitrogen gas and stirred for 1 h to allow the reaction; after the reaction was completed, ethyl acetate was added, and then centrifuged to obtain a precipitate; the precipitate was dissolved in ethanol, heptane was added to the ethanol, and then centrifuged again to obtain a ZnMgO—OAm intermediate;
0.06 mol of ZnMgO—OAm was dissolved in 100 mL of ethanol and heated to 50 °C with continuous stirring. After half an hour, 0.005 mol of the second ligand was added to perform a partial ligand exchange, and then stirred for another half an hour; ethyl acetate was added, and then centrifuged to obtain a precipitate; the precipitate was dissolved in ethanol, heptane was added to the ethanol solution, and then centrifuged again to obtain a precipitate, which was a ZnMgO—OAm-second ligand composite material.

### Example 2

This Example provides a composite material including an inorganic particle, the inorganic particles are linked with a first ligand and a second ligand, and the first ligand is configured to bond with the second ligand to link adjacent inorganic particles. The first ligand and the second ligand are linked through a covalent bond. The bonding method of the first ligand and the second ligand is photoinitiated polymerization. The composite material forms a network structure through the link of the inorganic particles.

The inorganic particle is ZnO doped with Al, and denoted as ZnAlO. The first ligand is oleylamine with a molecular formula of CH₃ (CH₂)₇CH═CH(CH₂)₇CH₂NH₂, and denoted as OAm. The second ligand is:

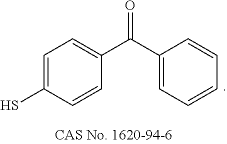 [SMILES: O=C(c1ccccc1)c1ccc(S)cc1]

A method for preparing the composite material of this Example includes the following steps:
0.12 mol of Zn(Ac)₂·2H₂O, 0.006 mol of Al(Ac)₂·4H₂O, and 0.05 mol of oleylamine (OAm) were simultaneously dissolved in 200 mL of N,N-dimethylformamide (DMF) solvent to obtain a first solution, and then introduced nitrogen gas and stirred for 1 h; 0.05 mol of potassium hydroxide was dissolved in 100 mL of an ethanol solution, and then stirred for 1 h; after the potassium hydroxide was complete dissolution, the potassium hydroxide solution achieved was injected into the first solution at an injection rate of 10 mL/min, and then introduced nitrogen gas and stirred for 1 h to allow the reaction; after the reaction was completed, ethyl acetate was added, and then centrifuged to obtain a precipitate; the precipitate was dissolved in ethanol, heptane was added to the ethanol, and then centrifuged again to obtain a ZnAlO—OAm intermediate;
0.06 mol of ZnAlO—OAm was dissolved in 100 mL of ethanol and heated to 50 °C with continuous stirring. After half an hour, 0.005 mol of the second ligand was added to perform a partial ligand exchange, and then stirred for another half an hour; ethyl acetate was added, and then centrifuged to obtain a precipitate; the precipitate was dissolved in ethanol, heptane was added to the ethanol solution, and then centrifuged again to obtain a precipitate, which was a ZnAlO—OAm-second ligand composite material.

### Example 3

The ZnMgO—OAm-second ligand composite material of Example 1 and the ZnAlO—OAm-second ligand composite material of Example 2 were mixed in an ethanol solution at a mass ratio of 1:1 to obtain a mixed composite material.

### Example 4

This Example provides a composite material including an inorganic particle, the inorganic particles are linked with a first ligand and a second ligand, and the first ligand is configured to bond with the second ligand to link adjacent inorganic particles. The first ligand and the second ligand are linked through a covalent bond. The bonding method of the first ligand and the second ligand is photoinitiated polymerization. The composite material forms a network structure through the link of the inorganic particles.

The inorganic particle is ZnO. The first ligand is oleylamine with a molecular formula of CH₃ (CH₂)₇CH═CH(CH₂)₇CH₂NH₂, and denoted as OAm. The second ligand is:

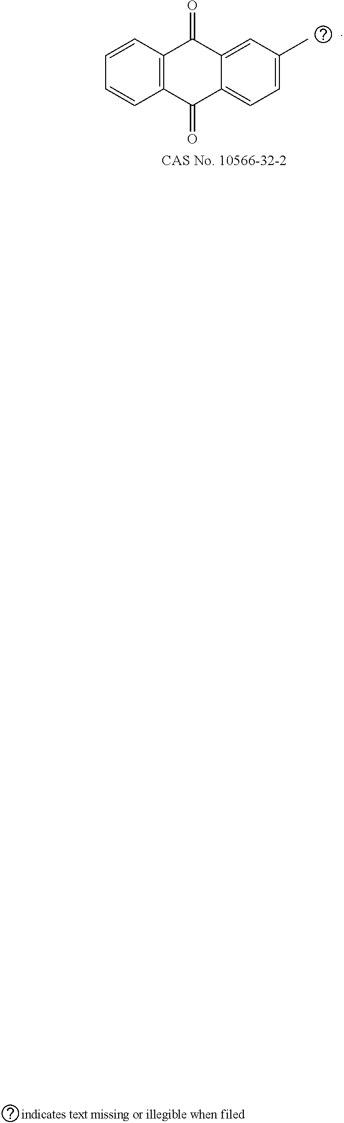 [SMILES: Cc1ccc2c(c1)C(=O)c1ccccc1C2=O]

The method for preparing the composite material of this Example was the same as that in the previous Example, with the difference that the molar ratio of the metal source, the first ligand, and the alkali was 3:1:1, and the molar ratio of the intermediate to the second ligand was 10:1.

### Example 5

This Example provides a composite material including an inorganic particle, the inorganic particles are linked with a first ligand and a second ligand, and the first ligand is configured to bond with the second ligand to link adjacent inorganic particles. The first ligand and the second ligand are linked through a covalent bond. The bonding method of the first ligand and the second ligand is photoinitiated polymerization. The composite material forms a network structure through the link of the inorganic particles.

The inorganic particle is NiO doped with Cl element; the first ligand is 9-octadecene; and the second ligand is:

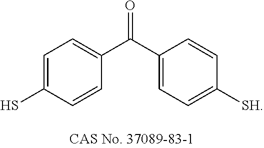 [SMILES: O=C(c1ccc(S)cc1)c1ccc(S)cc1]

The method for preparing the composite material of this embodiment was the same as that in the previous Example, with the difference that the molar ratio of the metal source, the doping source, the first ligand, and the alkali was 5:0.12:1:1; and the molar ratio of the intermediate to the second ligand was 5:1.

### Example 6

This Example provides a composite material including an inorganic particle, the inorganic particles are linked with a first ligand and a second ligand, and the first ligand is configured to bond with the second ligand to link adjacent inorganic particles. The first ligand and the second ligand are linked through a covalent bond. The bonding method of the first ligand and the second ligand is photoinitiated polymerization. The composite material forms a network structure through the link of the inorganic particles.

The inorganic particles are TiO₂ doped with graphene; the first ligand is octadecanethiol; and the second ligand is:

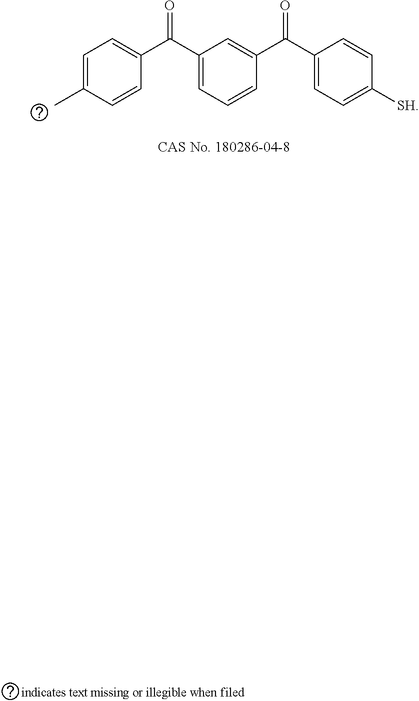 [SMILES: Cc1ccc(C(=O)c2cccc(C(=O)c3ccc(S)cc3)c2)cc1]

The method for preparing the composite material of this embodiment was the same as that in the previous Example, with the difference that the molar ratio of the metal source, the doping source, the first ligand, and the alkali was 2.5:0.2:1:1; and the molar ratio of the intermediate to the second ligand was 8:1.

### Example 7

This Example provides a composite material including an inorganic particle, the inorganic particles are linked with a first ligand and a second ligand, and the first ligand is configured to bond with the second ligand to link adjacent inorganic particles. The first ligand and the second ligand are linked through a covalent bond. The bonding method of the first ligand and the second ligand is photoinitiated polymerization. The composite material forms a network structure through the link of the inorganic particles.

The inorganic particle is BaTiO₃ doped with poly(3,4-ethylenedioxythiophene) polystyrene sulfonate (PEDOT:PSS); the first ligand is oleylamine; and the second ligand is:

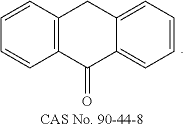 [SMILES: O=C1c2ccccc2Cc2ccccc21]

The method for preparing the composite material of this embodiment was the same as that in the previous Example, with the difference that the molar ratio of the metal source, the doping source, the first ligand, and the alkali was 2:0.18:1:1; and the molar ratio of the intermediate to the second ligand was 5:1.

### Example 8

This Example provides a composite material including an inorganic particle, the inorganic particles are linked with a first ligand and a second ligand, and the first ligand is configured to bond with the second ligand to link adjacent inorganic particles. The first ligand and the second ligand are linked through a covalent bond. The bonding method of the first ligand and the second ligand is photoinitiated polymerization. The composite material forms a network structure through the link of the inorganic particles.

The inorganic particle is ZnO; the first ligand is oleylamine; and the second ligand is:

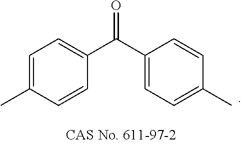

The method for preparing the composite material of this embodiment was the same as that in the previous Example, with the difference that the molar ratio of the metal source, the first ligand, and the alkali was 4:1:1; and the molar ratio of the intermediate to the second ligand was 6:1.

### Example 9

This Example provides a light-emitting device including a cathode, a first electron transport layer, a second electron transport layer, a light-emitting layer, a hole transport layer, a hole injection layer, and an anode, which are sequentially disposed on a substrate. The substrate is a glass sheet, a material of the cathode is ITO, a material of the light-emitting layer is a CdSe quantum dot, a material of the hole transport layer is poly(N-vinylcarbazole) (PVK), a material of the hole injection layer is PEDOT:PSS, the composite material prepared in Example 1 is used as the material of the first electron transport layer, and the composite material prepared in Example 2 is used as the material of the second electron transport layer.

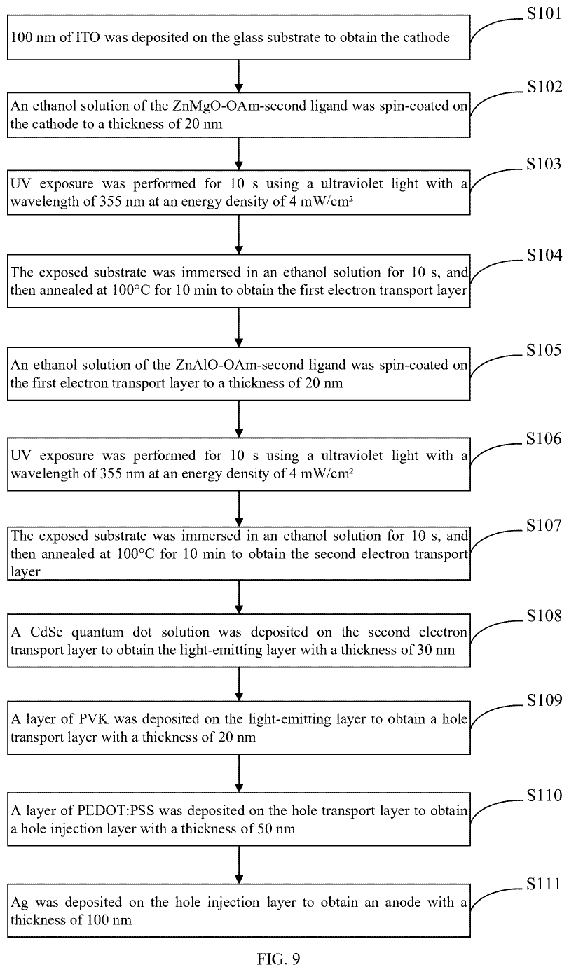

Referring to FIG. 9, a method for preparing the light-emitting device is as follows:
S101: 100 nm of ITO was deposited on the glass substrate to obtain the cathode;
S102: An ethanol solution of the ZnMgO—OAm-second ligand was spin-coated on the cathode to a thickness of 20 nm;
S103: UV exposure was performed for 10 s using a ultraviolet light with a wavelength of 355 nm at an energy density of 4 mW/cm²;
S104: The exposed substrate was immersed in an ethanol solution for 10 s, and then annealed at 100 °C for 10 min to obtain the first electron transport layer;
S105: An ethanol solution of the ZnAlO—OAm-second ligand was spin-coated on the first electron transport layer to a thickness of 20 nm;
S106: UV exposure was performed for 10 s using a ultraviolet light with a wavelength of 355 nm at an energy density of 4 mW/cm²;
S107: The exposed substrate was immersed in an ethanol solution for 10 s, and then annealed at 100 °C for 10 min to obtain the second electron transport layer;
S108: A CdSe quantum dot solution was deposited on the second electron transport layer to obtain the light-emitting layer with a thickness of 30 nm;
S109: A layer of PVK was deposited on the light-emitting layer to obtain a hole transport layer with a thickness of 20 nm;
S110: A layer of PEDOT:PSS was deposited on the hole transport layer to obtain a hole injection layer with a thickness of 50 nm.
S111: Ag was deposited on the hole injection layer to obtain an anode with a thickness of 100 nm.

### Example 10

This Example provides a light-emitting device including a cathode, an electron transport layer, a light-emitting layer, a hole transport layer, a hole injection layer, and an anode, which are sequentially disposed on a substrate. The substrate is a glass sheet, a material of the cathode is ITO, a material of the light-emitting layer is a CdZnS quantum dot, a material of the hole transport layer is PVK, a material of the hole injection layer is PEDOT:PSS, and the composite material prepared in Example 3 is selected as the material of the electron transport layer.

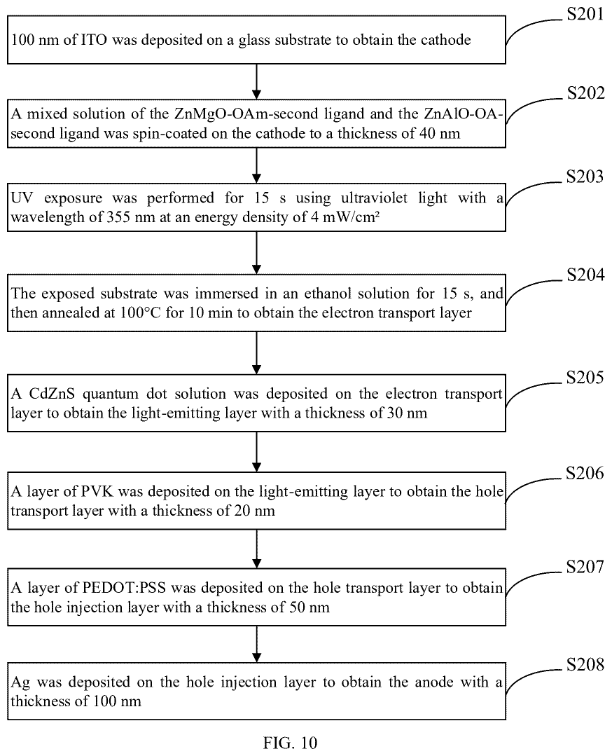

Referring to FIG. 10, a method for preparing the light-emitting device is as follows:
S201: 100 nm of ITO was deposited on a glass substrate to obtain the cathode;
S202: A mixed solution of the ZnMgO—OAm-second ligand and the ZnAlO-OA-second ligand was spin-coated on the cathode to a thickness of 40 nm;
S203: UV exposure was performed for 15 s using ultraviolet light with a wavelength of 355 nm at an energy density of 4 mW/cm²;
S204: The exposed substrate was immersed in an ethanol solution for 15 s, and then annealed at 100 °C for 10 min to obtain the electron transport layer;
S205: A CdZnS quantum dot solution was deposited on the electron transport layer to obtain the light-emitting layer with a thickness of 30 nm;
S206: A layer of PVK was deposited on the light-emitting layer to obtain the hole transport layer with a thickness of 20 nm;
S207: A layer of PEDOT:PSS was deposited on the hole transport layer to obtain the hole injection layer with a thickness of 50 nm;
S208: Ag was deposited on the hole injection layer to obtain the anode with a thickness of 100 nm.

### Example 11

This Example provides a light-emitting device. The light-emitting device has an upright stacked structure, including an anode, a hole injection layer, a hole transport layer, a light-emitting layer, an electron transport layer, a hole injection layer, a hole transport layer, a light-emitting layer, an electron transport layer, and a cathode, which are sequentially disposed on a substrate. The substrate is a glass sheet, a material of the anode is ITO, a material of the light-emitting layer is a CdSe quantum dot, a material of the hole transport layer is PVK, a material of the hole injection layer is PEDOT:PSS, and the composite material prepared in Example 1 is used as the material of the electron transport layer.

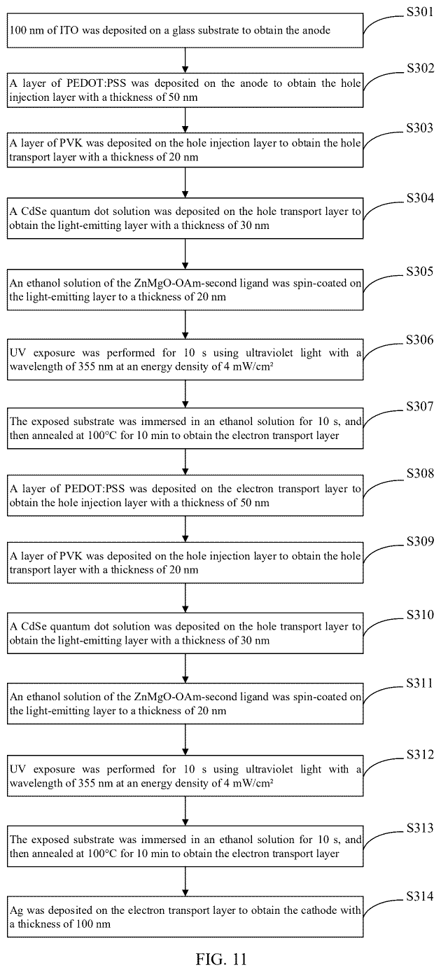

Referring to FIG. 11, a method for preparing the light-emitting device is as follows:
S301: 100 nm of ITO was deposited on a glass substrate to obtain the anode;
S302: A layer of PEDOT:PSS was deposited on the anode to obtain the hole injection layer with a thickness of 50 nm;
S303: A layer of PVK was deposited on the hole injection layer to obtain the hole transport layer with a thickness of 20 nm;
S304: A CdSe quantum dot solution was deposited on the hole transport layer to obtain the light-emitting layer with a thickness of 30 nm;
S305: An ethanol solution of the ZnMgO—OAm-second ligand was spin-coated on the light-emitting layer to a thickness of 20 nm;
S306: UV exposure was performed for 10 s using ultraviolet light with a wavelength of 355 nm at an energy density of 4 mW/cm²;
S307: The exposed substrate was immersed in an ethanol solution for 10 s, and then annealed at 100 °C for 10 min to obtain the electron transport layer;
S308: A layer of PEDOT:PSS was deposited on the electron transport layer to obtain the hole injection layer with a thickness of 50 nm;
S309: A layer of PVK was deposited on the hole injection layer to obtain the hole transport layer with a thickness of 20 nm.
S310: A CdSe quantum dot solution was deposited on the hole transport layer to obtain the light-emitting layer with a thickness of 30 nm;
S311: An ethanol solution of the ZnMgO—OAm-second ligand was spin-coated on the light-emitting layer to a thickness of 20 nm;
S312: UV exposure was performed for 10 s using ultraviolet light with a wavelength of 355 nm at an energy density of 4 mW/cm²;
S313: The exposed substrate was immersed in an ethanol solution for 10 s, and then annealed at 100 °C for 10 min to obtain the electron transport layer;
S314: Ag was deposited on the electron transport layer to obtain the cathode with a thickness of 100 nm.

### Example 12

This Example provides a light-emitting device including an anode, a hole injection layer, a hole transport layer, a light-emitting layer, an electron transport layer, and a cathode, which are sequentially disposed on a substrate. In this example, the substrate is a glass sheet, a material of the anode is ITO, a material of the light-emitting layer is a CdS quantum dot, a material of the hole transport layer is PVK, a material of the hole injection layer is PEDOT:PSS, and the composite material prepared in Example 2 is used as the material of the electron transport layer.

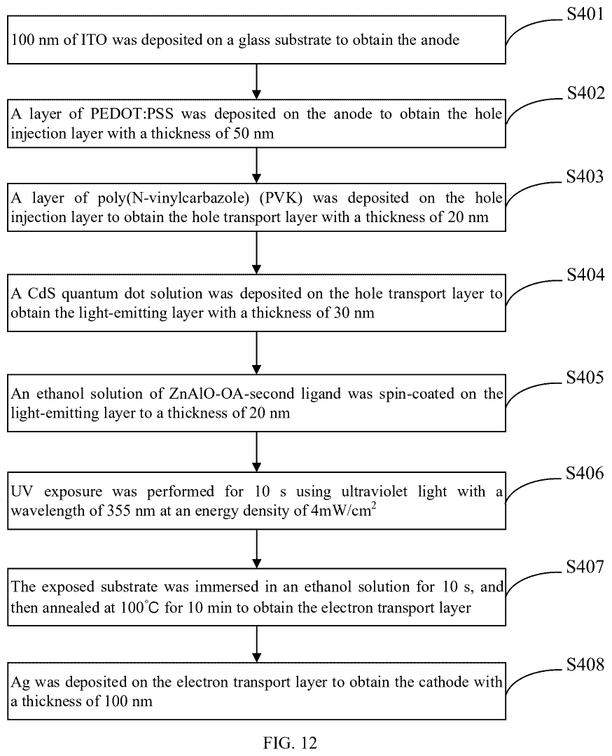

Referring to FIG. 12, a method for preparing the light-emitting device is as follows:
S401: 100 nm of ITO was deposited on a glass substrate to obtain the anode;
S402: A layer of PEDOT:PSS was deposited on the anode to obtain the hole injection layer with a thickness of 50 nm;
S403: A layer of poly(N-vinylcarbazole) (PVK) was deposited on the hole injection layer to obtain the hole transport layer with a thickness of 20 nm;
S404: A CdS quantum dot solution was deposited on the hole transport layer to obtain the light-emitting layer with a thickness of 30 nm;
S405: An ethanol solution of ZnAlO-OA-second ligand was spin-coated on the light-emitting layer to a thickness of 20 nm;
S406: UV exposure was performed for 10 s using ultraviolet light with a wavelength of 355 nm at an energy density of 4 mW/cm²;
S407: The exposed substrate was immersed in an ethanol solution for 10 s, and then annealed at 100 °C for 10 min to obtain the electron transport layer;
S408: Ag was deposited on the electron transport layer to obtain the cathode with a thickness of 100 nm.

### Example 13

This Example provides a light-emitting device including a cathode, a first electron transport layer, a second electron transport layer, a light-emitting layer, a hole transport layer, a hole injection layer, and an anode, which are sequentially disposed on a substrate. The substrate is a glass sheet, a material of the cathode is indium tin oxide (ITO), a material of the light-emitting layer is a CdSe quantum dot, a material of the hole transport layer is PVK, a material of the hole injection layer is poly(3,4-ethylenedioxythiophene) polystyrene sulfonate (PEDOT:PSS), a material of the first electron transport layer is the composite material prepared in Example 4, and a material of the second electron transport layer is the composite material prepared in Example 5.

The specific preparation process is the same as the Example 9.

### Example 14

This Example provides a light-emitting device including a cathode, an electron transport layer, a light-emitting layer, a hole transport layer, a hole injection layer, and an anode, which are sequentially disposed on a substrate. The substrate is a glass sheet, a material of the cathode is ITO, a material of the light-emitting layer is a CdZnS quantum dot, a material of the hole transport layer is PVK, a material of the hole injection layer is PEDOT:PSS, and a material of the electron transport layer is a mixed material of the composite material prepared in Example 6 and the composite material Example 7 at a mass ratio of 1:1.

The specific preparation process is the same as the Example 10.

### Example 15

This Example provides a light-emitting device including an anode, a hole injection layer, a hole transport layer, a light-emitting layer, an electron transport layer, and a cathode, which are sequentially disposed on a substrate. The substrate is a glass sheet, a material of the anode is ITO, a material of the light-emitting layer is a CdS quantum dot, a material of the hole transport layer is PVK, a material of the hole injection layer is PEDOT:PSS, and a material of the electron transport layer is the composite material prepared in Example 8.

The specific preparation process is the same as the Example 12.

### Comparative Example 1

This Comparative Example provides a light-emitting device including a cathode, a first electron transport layer, a second electron transport layer, a light-emitting layer, a hole transport layer, a hole injection layer, and an anode, which are sequentially disposed on a substrate. The substrate is a glass sheet; a material of the cathode is ITO; a material of the light-emitting layer is CdSe quantum dots; a material of the hole transport layer is PVK; a material of the hole injection layer is PEDOT:PSS; a material of the first electron transport layer is Mg-doped zinc oxide, and denoted as ZnMgO; and a material of the second electron transport layer is Al-doped zinc oxide, and denoted as ZnAlO.

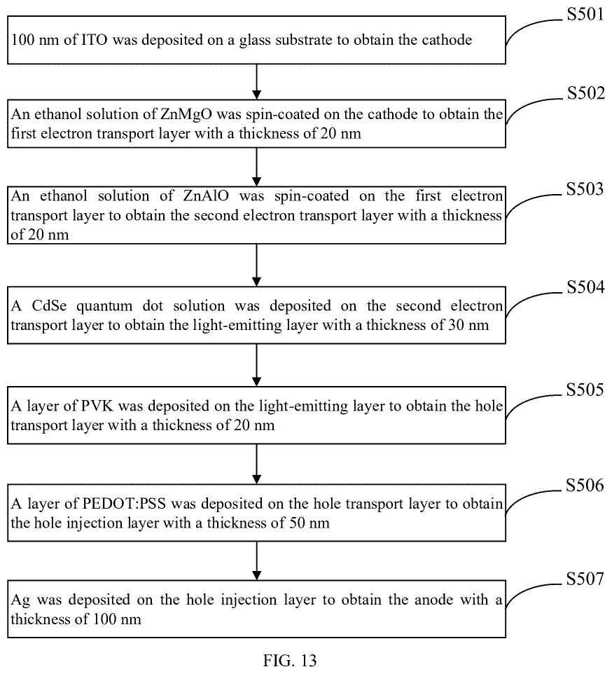

Referring to FIG. 13, a method for preparing the light-emitting device is as follows:
S501: 100 nm of ITO was deposited on a glass substrate to obtain the cathode;
S502: An ethanol solution of ZnMgO was spin-coated on the cathode to obtain the first electron transport layer with a thickness of 20 nm;
S503: An ethanol solution of ZnAlO was spin-coated on the first electron transport layer to obtain the second electron transport layer with a thickness of 20 nm;
S504: A CdSe quantum dot solution was deposited on the second electron transport layer to obtain the light-emitting layer with a thickness of 30 nm;
S505: A layer of PVK was deposited on the light-emitting layer to obtain the hole transport layer with a thickness of 20 nm;
S506: A layer of PEDOT:PSS was deposited on the hole transport layer to obtain the hole injection layer with a thickness of 50 nm;
S507: Ag was deposited on the hole injection layer to obtain the anode with a thickness of 100 nm.

### Comparative Example 2

This Comparative Example provides a light-emitting device including a cathode, an electron transport layer, a light-emitting layer, a hole transport layer, a hole injection layer, and an anode, which are sequentially disposed on a substrate. The substrate is a glass sheet, a material of the cathode is ITO, a material of the light-emitting layer is a CdZnS quantum dot, a material of the hole transport layer is PVK, a material of the hole injection layer is PEDOT:PSS, and a material of the electron transport layer is the intermediate prepared in Example 1, that is ZnMgO—OAm.

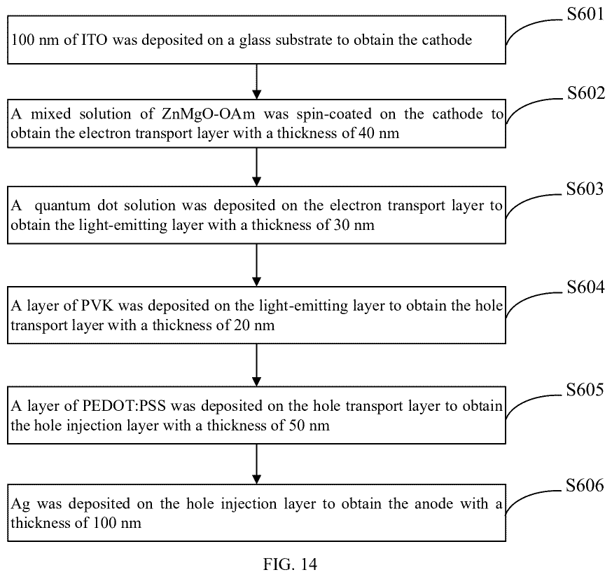

Referring to FIG. 14, a method for preparing the light-emitting device is as follows:
S601: 100 nm of ITO was deposited on a glass substrate to obtain the cathode;
S602: A mixed solution of ZnMgO—OAm was spin-coated on the cathode to obtain the electron transport layer with a thickness of 40 nm;
S603: A CdZnS quantum dot solution was deposited on the electron transport layer to obtain the light-emitting layer with a thickness of 30 nm;
S604: A layer of PVK was deposited on the light-emitting layer to obtain the hole transport layer with a thickness of 20 nm;
S605: A layer of PEDOT:PSS was deposited on the hole transport layer to obtain the hole injection layer with a thickness of 50 nm;
S606: Ag was deposited on the hole injection layer to obtain the anode with a thickness of 100 nm.

### Comparative Example 3

This Comparative Example provides a light-emitting device including an anode, a hole injection layer, a hole transport layer, a light-emitting layer, an electron transport layer, and a cathode, which are sequentially disposed on a substrate. The substrate is a glass sheet; a material of the anode is ITO; a material of the light-emitting layer is a CdS quantum dot; a material of the hole transport layer is PVK; a material of the hole injection layer is PEDOT:PSS; and a material of the electron transport layer is Mg-doped zinc oxide, and denoted as ZnMgO.

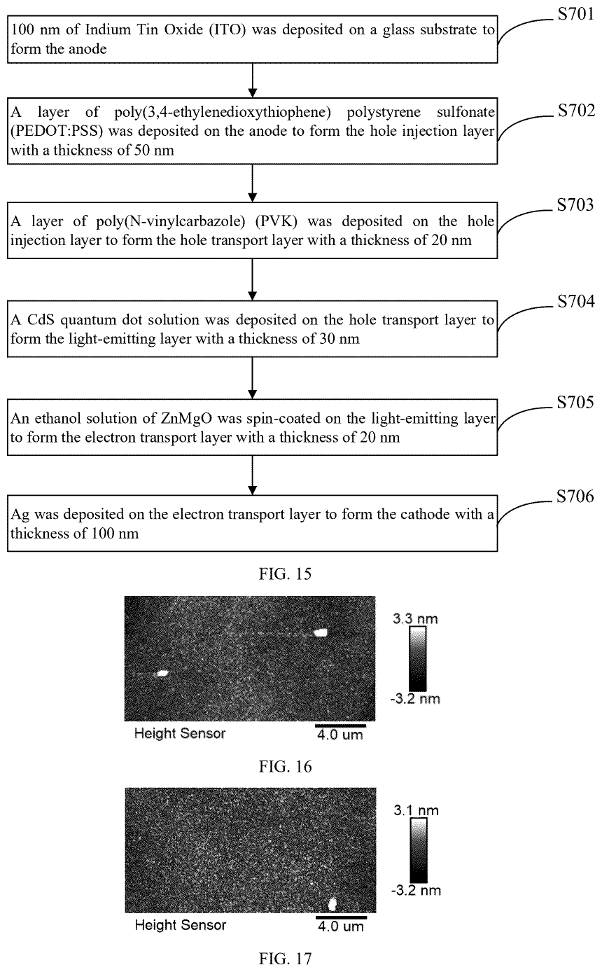

Referring to FIG. 15, a method for preparing the light-emitting device is as follows:
S701: 100 nm of Indium Tin Oxide (ITO) was deposited on a glass substrate to form the anode;
S702: A layer of poly(3,4-ethylenedioxythiophene) polystyrene sulfonate (PEDOT:PSS) was deposited on the anode to form the hole injection layer with a thickness of 50 nm;
S703: A layer of poly(N-vinylcarbazole) (PVK) was deposited on the hole injection layer to form the hole transport layer with a thickness of 20 nm;
S704: A CdS quantum dot solution was deposited on the hole transport layer to form the light-emitting layer with a thickness of 30 nm;
S705: An ethanol solution of ZnMgO was spin-coated on the light-emitting layer to form the electron transport layer with a thickness of 20 nm;
S706: Ag was deposited on the electron transport layer to form the cathode with a thickness of 100 nm.

The light-emitting devices of Examples 9-15 and Comparative Examples 1-3 were characterized for performance, and the test data are shown in Table 1. The tested performance parameter was external quantum efficiency (EQE, %), and the performance test results are detailed in Table 1 below.

External quantum efficiency (EQE) was measured using an EQE optical testing instrument.

The electron transport layers of the light-emitting devices of Examples 9-10 and Comparative Examples 1-2 were tested by atomic force microscopy (AFM), and the surface roughness is detailed in Table 2 below.

TABLE 1

| | EQE % |
|---|---|
| Example 9 | 13.3 |
| Example 10 | 15.2 |
| Example 11 | 16.2 |
| Example 12 | 14.5 |
| Example 13 | 13.8 |
| Example 14 | 14.9 |
| Example 15 | 15.5 |
| Comparative Example 1 | 3.5 |
| Comparative Example 2 | 4.5 |
| Comparative Example 3 | 2.8 |

TABLE 2

| | Surface |
|---|---|
| | Roughness |
| | (Ra nm) |
| Example 9 | 1.28 |
| Example 10 | 1.02 |
| Comparative Example 1 | 4.30 |
| Comparative Example 2 | 2.50 |

As shown in Table 1, compared with Comparative Examples 1-3, the light-emitting devices of Examples 9-15 of the present application all exhibit higher external quantum efficiencies after using the composite material provided in the present Examples. This indicates that for both conventional structure and inverted structure light-emitting devices, using the composite material of the present embodiment may significantly improve the performance of the light-emitting devices.

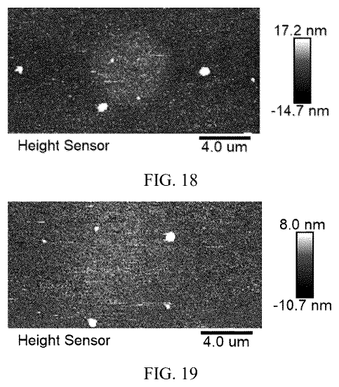

Referring to FIG. 16, FIG. 17, FIG. 18, and FIG. 19, in conjunction with the data in Table 2, the surface roughness of the light-emitting devices in Examples 9-10 is lower than that of the light-emitting devices in Comparative Examples 1-2. This indicates that the electron transport layer prepared using the composite material of the present embodiment has higher stability. Meanwhile, in FIG. 18 and FIG. 19, a ring pattern may be seen in the central part. The appearance of the ring pattern indicates a large difference in thickness between its inner and outer parts. This also indirectly indicates that the electron transport layers of Comparative Example 1 and Comparative Example 2 are susceptible to being washed away by organic solvents. However, the electron transport layer of the present application has strong resistance to solution washing because a network structure is formed by internal cross-linking.

A composite material and a preparation method therefor, a light-emitting device and a display device provided by the embodiments of the present application are described in detail above. The principle and implementation mode of the present application are described herein by applying specific examples, and the description of the above embodiments is only for helping to understand the method and core idea of the present application. Meanwhile, those skilled in the art may change the specific embodiments and the scope of application according to the ideas of the present application, and in summary, the contents of the present specification should not be construed as limiting the present application.

1. A composite material, comprising:
an inorganic particle, wherein the inorganic particle is linked with a first ligand and a second ligand, and the first ligand is linked to the second ligand.

2. The composite material according to claim 1, wherein the first ligand and the second ligand are linked through a covalent bond;
the composite material has a network structure; and
a molar ratio of the first ligand to the second ligand ranges from 5:1 to 12:1.

3. The composite material according to claim 2, wherein the first ligand is selected from one or more of a chain hydrocarbon having 1-30 carbon atoms, a cyclic hydrocarbon having 3-30 ring atoms, an aromatic hydrocarbon having 6-40 ring atoms, a carboxylic acid having 1-30 carbon atoms, an amine having 1-30 carbon atoms, and a thiol having 1-30 carbon atoms, which are unsubstituted or substituted with an amino group, a halogen, a hydroxyl group, a carboxyl group, a nitro group, a sulfonic acid group, an aldehyde group, a mercapto group, or a cyano group; and the second ligand is selected from one or more of a ketone, a ketone derivative, a quinone, and a quinone derivative.

4. The composite material according to claim 3, wherein the first ligand is selected from one or more of R₁—CH₃, R₂—COOH, R₃—NH₂, and R₄—SH;
where R₁, R₂, R₃, and R₄ are each independently selected from a chain hydrocarbon group having 1-20 carbon atoms and an aromatic hydrocarbon group having 6-18 ring atoms, which are unsubstituted or substituted with an amino group, a halogen, a hydroxyl group, a carboxyl group, a nitro group, a sulfonic acid group, an aldehyde group, a mercapto group, or a cyano group.

5. The composite material according to claim 4, wherein the second ligand is selected from one or more of R₅—CO—R₆, R₇—CO-M-CO—R₈, cyclohexadienedione or a derivative thereof;
where R₅, R₆, R₇, and R₈ are each independently selected from a hydrocarbon group having 1-20 carbon atoms and an aromatic hydrocarbon group having 6-18 ring atoms, which are unsubstituted or substituted with an amino group, a halogen, a hydroxyl group, a carboxyl group, a nitro group, a sulfonic acid group, an aldehyde group, a mercapto group, or a cyano group; and
M is selected from a single bond, —O—, —S—, —CO—, —CO—O—, —O—CO—, —O—CO—O—, —CH—N—, —N═CH—, —N—N—, a hydrocarbylene group having 1-20 carbon atoms, and an arylene group having 5-18 ring atoms.

6. The composite material according to claim 5, wherein the first ligand is selected from one or more of R₁—CH₃, R₂—COOH, R₃—NH₂, and R₄—SH; where R₁, R₂, R₃ and R₄ are each independently selected from a chain hydrocarbon group having 4-18 carbon atoms and an aromatic hydrocarbon group having 6-18 ring atoms;
the second ligand is selected from one or more of the following formulas (1) to (6):

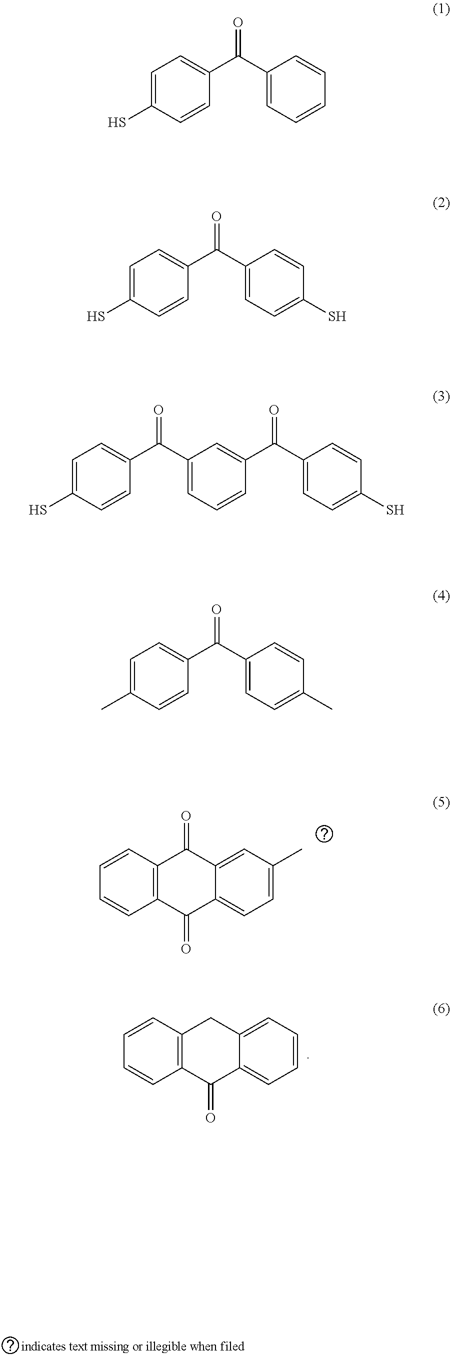

7. The composite material according to claim 1, wherein the inorganic particle is selected from one or more of a metal oxide and a doped metal oxide;
where a doping substance in the doped metal oxide is selected from one or more of a metal, a halogen, an inorganic substance, and an organic polymer; and
an average particle size of the inorganic particle ranges from 10 nm to 15 nm.

8. The composite material according to claim 7, wherein the metal oxide is selected from one or more of ZnO, NiO, W₂O₃, Mo₂O₃, TiO₂, SnO, ZrO₂, Ta₂O₃, Ga₂O₃, Al₂O₃, CaO, and HfO₂; and
the metal is selected from one or more of Mg, Ca, Li, Ga, Al, Co, Mn, and K.

9. The composite material according to claim 8, wherein the halogen is selected from one or more of F, Cl, Br, and I;
the inorganic substance is selected from one or more of graphene, fullerene, and molybdenum disulfide; and
the organic polymer is selected from one or more of PEDOT:PSS, polyaniline, polypyrrole, polythiophene, and poly(p-phenylene vinylene).

10. A method for preparing a composite material, comprising the following steps:
providing a first solution containing a metal source and a first ligand, and a second solution containing a second ligand;
mixing the first solution with an alkaline solution to obtain a third solution, and the third solution comprises an inorganic particle linked with the first ligand; and
mixing the third solution with the second solution, followed by reacting, centrifuging, and precipitating to obtain the composite material;
wherein the composite material comprises the inorganic particle, the inorganic particle is linked with the first ligand and the second ligand, and the first ligand is linked to the second ligand.

11. The method for preparing a composite material according to claim 10, wherein the first ligand is selected from one or more of R₁—CH₃, R₂—COOH, R₃—NH₂, and R₄—SH; where R₁, R₂, R₃, and R₄ are each independently selected from a chain hydrocarbon group having 4-18 carbon atoms and an aromatic hydrocarbon group having 6-18 ring atoms;
the second ligand is selected from one or more of the following formulas (1) to (6):

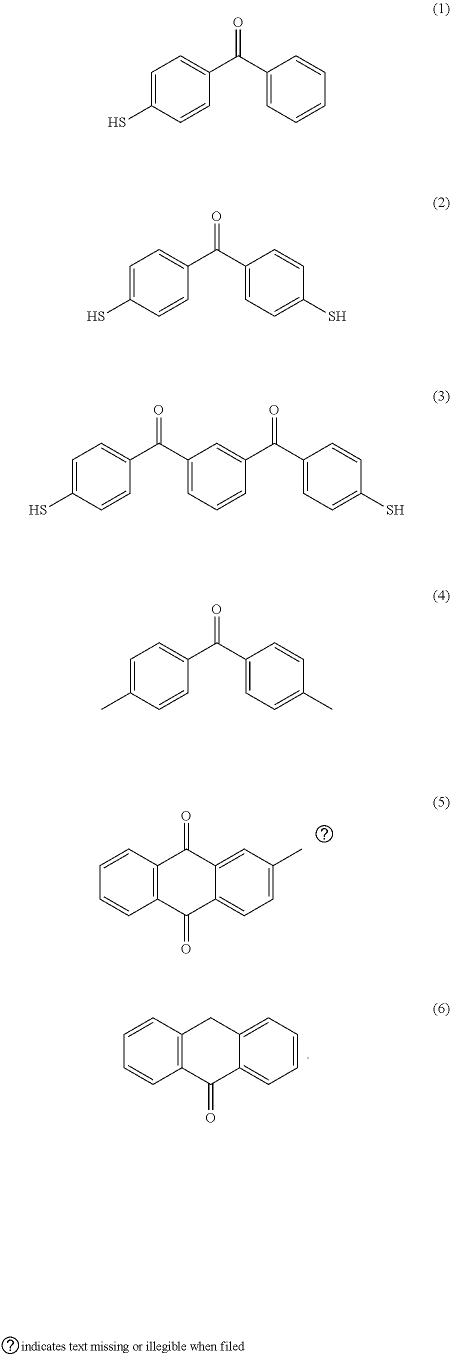

12. The method for preparing a composite material according to claim 10, wherein a metal in the metal source is a first metal, and the first metal is selected from one or more of Zn, Ni, W, Mo, Ti, Sn, Zr, Ta, Ga, Al, Ca, and Hf.

13. The method for preparing a composite material according to claim 10, wherein the first solution further comprises a doping source, and a doping substance in the doping source is selected from one or more of a second metal, a halogen, an inorganic substance, and an organic polymer.

14. The method for preparing a composite material according to claim 13, wherein
a molar ratio of the metal source, the doping source, the first ligand, and an alkali in the alkaline solution is (2-5):(0.1-0.2):1:1;
a molar ratio of the inorganic particles linked to the first ligand to the second ligand is (5-12):1; and
a molar ratio of the first ligand to the second ligand is (5-12):1.

15. The method for preparing a composite material according to claim 13, wherein the second metal is selected from one or more of Mg, Ca, Li, Ga, Al, Co, Mn, and K;
the halogen is selected from one or more of F, Cl, Br, and I;
the inorganic substance is selected from one or more of graphene, fullerene, and molybdenum disulfide; and the organic polymer is selected from one or more of PEDOT:PSS, polyaniline, polypyrrole, polythiophene, and poly(p-phenylene vinylene).

16. A light-emitting device, comprising:
a first electrode, a light-emitting layer, and a second electrode; and the light-emitting device further comprises at least one electron transport layer disposed between the first electrode and the light-emitting layer;
wherein the electron transport layer comprises a composite material, the composite material comprises an inorganic particle, the inorganic particle is linked with a first ligand and a second ligand, and the first ligand is linked to the second ligand.

17. The light-emitting device according to claim 16, wherein the first ligand is selected from one or more of R₁—CH₃, R₂—COOH, R₃—NH₂, and R₄—SH; where R₁, R₂, R₃ and R₄ are each independently selected from a chain hydrocarbon group having 4-18 carbon atoms and an aromatic hydrocarbon group having 6-18 ring atoms;
the second ligand is selected from one or more of the following formulas (1) to (6): 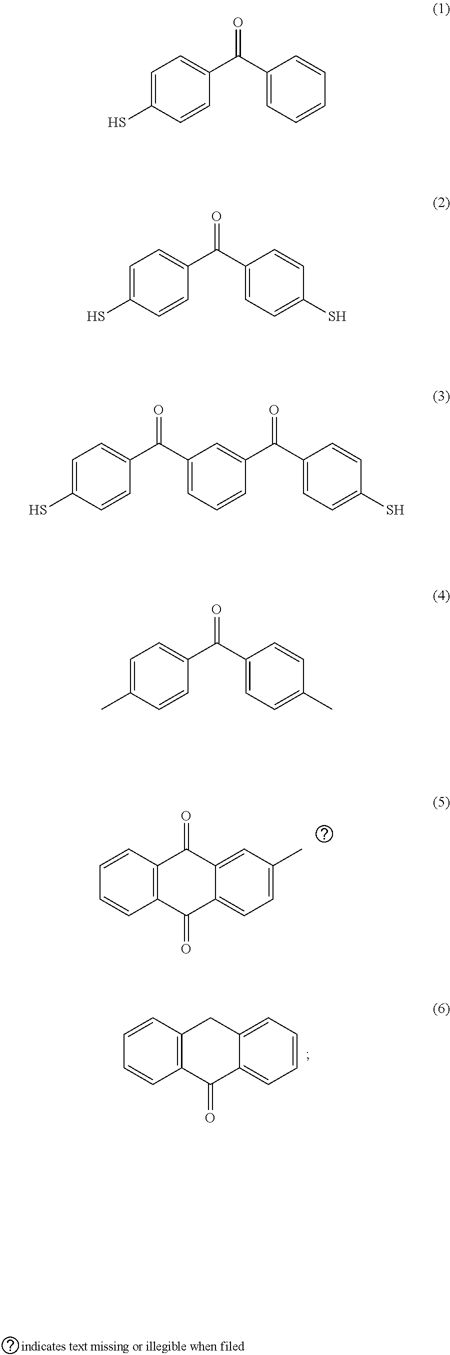
the inorganic particle is selected from one or more of a metal oxide and a doped metal oxide, and a doping substance in the doped metal oxide is selected from one or more of a metal, a halogen, an inorganic substance, and an organic polymer.

18. The light-emitting device according to claim 16,
wherein the electron transport layer comprises a first electron transport layer and a second electron transport layer that are stacked;
the first electrode is an anode, and the second electrode is a cathode; or the first electrode is a cathode, and the second electrode is an anode;
the composite material of the first electron transport layer comprises a first inorganic particle, the first inorganic particle is selected from a first doped metal oxide, and a doping substance in the first doped metal oxide is selected from one or more of Ga, Li, Mg, Mn, and a halogen;
the composite material of the second electron transport layer comprises a second inorganic particle, the second inorganic particle is selected from a second doped metal oxide, and a doping substance in the second doped metal oxide is selected from one or more of Al, K, graphene, fullerene, molybdenum disulfide, PEDOT:PSS, polyaniline, polypyrrole, polythiophene, and poly(p-phenylene vinylene);
a material of the anode and a material of the cathode comprise one or more of a metal, a carbon material, and a metal oxide; the metal comprises one or more of Al, Ag, Cu, Mo, Au, Ba, Ca, Yb, and Mg; the carbon material comprises one or more of graphite, a carbon nanotube, graphene, and a carbon fiber; the metal oxide comprises one or more of a doped or undoped metal oxide, and the doped metal oxide comprises one or more of ITO, FTO, ATO, AZO, GZO, IZO, MZO, and AMO; or the cathode is a composite electrode with a metal sandwiched between doped or undoped transparent metal oxides, and the composite electrode comprises one or more of AZO/Ag/AZO, AZO/AI/AZO, ITO/Ag/ITO, ITO/Al/ITO, ZnO/Ag/ZnO, ZnO/Al/ZnO, ZnS/Ag/ZnS, ZnS/Al/ZnS, TiO₂/Ag/TiO₂, and TiO₂/Al/TiO₂;
the light-emitting layer is a quantum dot light-emitting layer or an organic light-emitting layer; a material of the quantum dot light-emitting layer comprises one or more of a single-structure quantum dot and a core-shell structure quantum dot; a material of the single-structure quantum dot is selected from one or more of a II-VI group compound, a IV-VI group compound, a III-V group compound, and a I-III-VI group compound, the II-VI group compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe, the IV-VI group compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe, the III-V group compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb, and the I-III-VI group compound is selected from one or more of CuInS₂, CuInSe₂, and AgInS₂.

19. The light-emitting device according to claim 18, wherein a core of the core-shell structure quantum dot comprises any one of the above-mentioned single-structure quantum dots, and a shell material of the core-shell structure quantum dot comprises one or more of CdS, CdTe, CdSeTe, CdZnSe, CdZnS, CdSeS, ZnSe, ZnSeS, ZnS, and the above-mentioned material of the single-structure quantum dot;
a material of the organic light-emitting layer comprises one or more of 4,4′-bis(N-carbazolyl)-1,1′-biphenyl: tris[2-(p-tolyl)pyridine-C₂,N)iridium (III), 4,4′,4″-tris(carbazol-9-yl)triphenylamine: tris[2-(p-tolyl)pyridine-C₂,N)iridium (III), a diaryl anthracene derivative, a styryl aromatic derivative, a pyrene derivative, a fluorene derivative, a TBPe fluorescent material, a TTPX fluorescent material, a TBRb fluorescent material, a DBP fluorescent material, polyacetylene and a derivative thereof, poly(p-phenylene) and a derivative thereof, polythiophene and a derivative thereof, and polyfluorene and a derivative thereof;
the light-emitting device further comprises an electron injection layer, a hole transport layer, and a hole injection layer;
the electron injection layer is disposed between the first electrode and the electron transport layer, and a material of the electron injection layer comprises an inorganic material and an organic material; the inorganic material is selected from one or more of doped or undoped zinc oxide, barium oxide, aluminum oxide, nickel oxide, titanium oxide, tin oxide, tantalum oxide, zirconium oxide, lithium-doped titanium oxide, aluminum-doped zinc oxide, manganese-doped zinc oxide, tin-doped zinc oxide, lithium-doped zinc oxide, indium tin oxide, cadmium sulfide, zinc sulfide, molybdenum sulfide, tungsten sulfide, copper sulfide, zinc stannide, indium phosphide, gallium phosphide, copper indium sulfide, copper gallium sulfide, and barium titanate, where a doping element comprises one or more of aluminum, magnesium, lithium, manganese, yttrium, lanthanum, copper, nickel, zirconium, cerium, and gadolinium; the organic material is selected from one or more of a quinoxaline compound, an imidazole compound, a triazine compound, a fluorene-containing compound, and a hydroxyquinoline compound.

20. The light-emitting device according to claim 18, wherein the hole transport layer is disposed between the light-emitting layer and the second electrode, and the hole injection layer is disposed between the hole transport layer and the second electrode; and a material of the hole transport layer and a material the hole injection layer comprises one or more of TFB, CuPc, PVK, Poly-TPD, DNTPD, TCATA, TCCA, CBP, TPD, NPB, NPD, PEDOT:PSS, TAPC, MCC, F4-TCNQ, HATCN, 4,4′,4′-tris(N-3-methylphenyl-N-phenylamino)triphenylamine, polyaniline, a transition metal oxide, a transition metal sulfide, a transition metal stannide, doped graphene, undoped graphene, and C₆₀.
